(19) United States
(12) Patent Application Publication
(10) Pub. No.: US 2014/0020738 A1
(43) Pub. Date: Jan. 23, 2014

(54) SOLAR CELL, AND PROCESS FOR PRODUCING SOLAR CELL

(71) Applicants: Yasuhiro Aida, Tokyo (JP); Valerie Depredurand, Esch-sur-Alzette (LU); Susanne Siebentritt, Belvaux (LU)

(72) Inventors: Yasuhiro Aida, Tokyo (JP); Valerie Depredurand, Esch-sur-Alzette (LU); Susanne Siebentritt, Belvaux (LU)

(73) Assignees: UNIVERSITE DU LUXEMBOURG, Luxembourg (LU); TDK CORPORATION, Tokyo (JP)

(21) Appl. No.: 14/008,821

(22) PCT Filed: Mar. 28, 2012
(86) PCT No.: PCT/JP2012/059125

§ 371 Date: Sep. 30, 2013

(30) Foreign Application Priority Data
Apr. 4, 2011 (JP) 2011-083184

(51) Int. Cl. H01L 31/032

(52) U.S. Cl. CPC H01L 31/0322
USPC 136/255; 438/87

(57) ABSTRACT

A solar cell that can increase open-circuit voltage compared to the conventional solar cell, and as a result, can increase conversion efficiency. The solar cell includes a first absorber layer and a second absorber layer, wherein the first absorber layer is a p-type semiconductor layer containing a Ib group element, a IIIb group element, and a VIb group element and including a peak of luminescence whose half width is not less than 1 meV and not more than 15 meV in a photoluminescence spectrum or a cathodoluminescence spectrum; and the second absorber layer contains a Ib group element, a IIIb group element, and a VIb group element, the composition ratio of the Ib group element to the IIIb group element is not less than 0.1 and less than 1.0, and the second absorber layer is provided on the side of the light entering surface of the first absorber layer.

### TECHNICAL FIELD

The present invention relates to a solar cell and a process for producing a solar cell.

### BACKGROUND ART

Instead of bulk crystalline silicon solar cells that have been widespread, development of solar cells using a thin film semiconductor layer as an absorber layer has been progressed. Among them, thin film solar cells using a chalcopyrite compound semiconductor layer containing an element selected from the Ib group of the periodic table such as Cu, Ag or Au, an element selected from the IIIb group of the periodic table such as In, Ga, or Al, and an element selected from the VIb group of the periodic table such as O, S, Se, or Te as the absorber layer show high energy conversion efficiency and smaller effect of photo degradation compare to amorphous silicon solar cells; for this reason, the chalcopyrites thin film solar cells are expected as the solar cell in the next generation. Specifically, in thin film solar cells using a chalcopyrite p-type semiconductor film such as CuInSe₂ consisting of Cu, In, and Se (hereinafter, referred to as CISe) or Cu(In,Ga)Se₂ in which part of In as the IIIb group is replaced by Ga (hereinafter, referred to as CIGSe) as the absorber layer, high conversion efficiency is obtained. Particularly, it is said that high conversion efficiency is obtained by using a deposition method called a three stage process. (see Non Patent Literature 1)

### CITATION LIST

### Non Patent Literature

[Non Patent Literature 1] Prog. Photovolt: Res. Appl. (2008), 16: 235-239
[Non Patent Literature 2] Wide-Gap Chalcopyrites (Springer Series in MATERIALS SCIENCE), p. 146
[Non Patent Literature 3] Applied Physics Letters 63 (24) (1993), p. 3294
[Non Patent Literature 4] Wide-Gap Chalcopyrites (Springer Series in MATERIALS SCIENCE), p. 130

### SUMMARY OF INVENTION

### Technical Problem

With respect to the stoichiometric composition ratio of the Ib group element to the IIIb group element in the chalcopyrite type p-type semiconductor, Ib composition (atomic %)/IIIb composition (atomic %)=1.0. Hereinafter, Ib composition (atomic %)/IIIb composition (atomic %)<1.0 is referred to as an Ib-poor composition, while Ib composition (atomic %)/IIIb (atomic %)>1.0 is referred to as an Ib-rich composition. In an ordinary solar cell using the chalcopyrite type p-type absorber layer, it is regulated in the Ib-poor composition, and used. This is because if the element ratio of Ib/IIIb in the absorber layer exceeds the stoichiometric composition ratio to be Ib-rich, segregation of a secondary phase Ibx-VIb, i.e., a compound between the Ib group element and the VIb group element starts. In FIG. 3, as an example, a phase diagram between Cu₂Se and In₂Se₃ is shown. This secondary phase Ibx-VIb is a highly conductive material, and if this secondary phase exists in the absorber layer, a back electrode layer and an n-type semiconductor window layer are short-circuited, leading to significant deterioration in solar cell properties. Accordingly, usually, the chalcopyrite p-type semiconductor film with the Ib-rich composition has ever not been used as the absorber layer.

On the other hand, it is reported that the chalcopyrite p-type semiconductor film having the Ib-rich composition has better electrical properties than the film with the Ib-poor composition (see Non Patent Literature 2). According to Non Patent Literature 2, it is said that in a CIGSe film formed in a Cu-rich composition, defect density is small. In the case where this film is used for the absorber layer of the solar cell, it is thought that high conversion efficiency is obtained because transport properties of photo generated carriers are better. As described above, however, CISe, CGSe, and CIGSe having the Cu-rich composition have a secondary phase CuxSe, and for this reason, good transport properties of Cu-rich absorber can not be utilized for solar cells as they have been expected.

In order to solve this problem, there is a technique for selectively removing a secondary phase IbxSe (see Non Patent Literature 3). This is a technique for selectively etching only a secondary phase Ib group element-VIb group element compound from a film by immersing the film in a potassium cyanide (KCN) aqueous solution. Thereby, only the chalcopyrite p-type semiconductor film formed in the Ib-rich composition can be used as the absorber layer. However, even if a solar cell is produced using this KCN-etched absorber layer, i.e., the absorber layer having no secondary phase conductive IbxSe layer, a high open-circuit voltage expected from good transport properties of the carriers that the Ib-rich composition film intrinsically has is not obtained and conversion efficiency is low, while properties are improved compared to those before etching.

Usually, when a semiconductor material is irradiated with light or an electron beam, luminescence referred to as photoluminescence (hereinafter, referred to as PL) and cathodoluminescence (hereinafter, referred to as CL) is obtained. In the chalcopyrite p-type semiconductor film used for the absorber layer of the solar cell, the same luminescence is obtained. The chalcopyrite semiconductor used for the absorber layer is usually a p-type semiconductor in which holes are a majority carrier, but has not only an acceptor that forms a hole but also a donor that forms an electron. The shapes of the PL spectrum and the CL spectrum are changed by various factors, and one of the factors is the concentration of the donor and the concentration of the acceptor. These luminescences are generated by energy transition between two levels, for example, between the conduction band minimum energy level and valence band maximum energy level, between the donor level and acceptor level, between an energy level that a free exciton forms and valence band maximum energy level, and the like. The majority carrier of the p-type semiconductor is the hole; however, if compensation for the majority carrier (hole) by the minority carrier (electron) is increased, the half width of the PL spectrum and CL spectrum is wider. This is because distribution of the energy level described above is fluctuated, the energy between the respective energy levels is changed, and thus, the luminescence having a variety of energy overlap.

As described above, the PL and CL spectrums strongly depend on the energy level state that exists in the semiconductor material. In the case where the p-type semiconductor film in which the PL and CL with a narrow half width can be observed is used as the absorber layer, the fluctuation of the energy level described above is small; for this reason, a carrier recombination rate is decreased, and transport properties of the photo generated carriers are increased. Thereby, improvement of the conversion efficiency can be expected.

It is known that the half width of the PL at a low temperature (10 K or less) in the chalcopyrite p-type semiconductor is influenced by the Ib group/IIIb group composition ratio (see Non Patent Literature 4). Usually, in the Ib-rich composition, excitonic luminescence with a narrow half width is observed.

As described above, one of the factors contributed to the half width of the PL or CL spectrum is a degree of the fluctuation of the energy level. Other than by forming the Ib-rich composition, by decreasing selenium vacancies by crystal growth under high selenium partial pressure, or by reducing the concentration of sodium mixed in the film, the carrier compensation effect is reduced; thus, the PL or CL with a narrow half width can be obtained. However, even if the absorber layer having the PL with a narrow half width produced by one of the processes is used to produce a solar cell, high conversion efficiency expected from good carrier transport properties is not obtained.

The present inventors have found out that there is a problem below as the reason that good carrier transport properties cannot be utilized and the conversion efficiency cannot be improved even if the PL or CL with a narrow half width is obtained, and the absorber layer from which the highly conductive secondary phase is selectively removed is used.

As an example of the solar cell properties in the case where the chalcopyrite p-type semiconductor having the PL or CL spectrum with a narrow half width and containing no secondary phase is used for the absorber layer of the solar cell, an example of values of a reverse saturation current density j₀, a parallel resistance R_{P}, an open-circuit voltage V_{OC}, a short-circuit current density J_{SC}, a fill factor FF, and a conversion efficiency η in the solar cell using a layer from which a secondary phase CuxSe is removed by KCN etching on a Cu-rich CuInSe₂ thin film as the absorber layer is shown below. The half width of the PL spectrum at 10 K (kelvin) in this layer was 7 meV, and the half width of the CL spectrum was 7 meV.

j₀: 5.11×10⁻⁸ (A/cm²), R_{P}: 185 (Ω·cm),
V_{OC}: 0.400 (V), J_{SC}: 33.5 (mA/cm²),

### FF: 0.603, η: 8.08(%)

The CuInSe₂ solar cell whose conversion efficiency is high usually shows a value of j₀ on the order of 10⁻⁷ to 10⁻¹¹ (A/cm²), and the value of R_{P} is not less than 500 (Ω·cm). It turns out that in the solar cell using the Cu-rich CuInSe₂ thin film as the absorber layer, the value of j₀ is larger and the value of R_{P} is smaller than those in the CuInSe₂ solar cell.

Usually, the equivalent circuit of a pn junction solar cell is represented by the following expression (1). Hereinafter, this model is referred to as a single diode model.

$$\begin{matrix}[ Expression 1 ] & \\ j = {j}_{0} ( {e}^{e ( V - {R}_{S} j ) / {Ak}_{B} T} - 1 ) + \frac{V - {R}_{S} j}{{R}_{P}} - {j}_{p h} & ( Expression 1 )\end{matrix}$$

j: current density
j₀: reverse saturation current density
jₚₕ: photocurrent density
e: elementary charge
V: voltage
A: diode factor
k_{B}: Bolzmann's constant
T: temperature
R_{S}: serial resistance
R_{P}: parallel resistance

Here, in order to find a cause of the low V_{OC} of the solar cell using the Cu-rich CuInSe₂ thin film, in which the PL and CL with a narrow half width were obtained and the KCN etching for removal of a secondary phase was performed, as the absorber layer, Expression 1 was used to perform simulation. The result in the case where j₀ is changed as a parameter is shown in FIG. 4, and the result in the case where Rp is changed is shown in FIG. 5. From this result, the present inventors have found out that the cause of the low V_{OC} is mainly a large reverse saturation current density j₀.

Usually, it is said that in the pn junction semiconductor solar cell, the reverse saturation current density j₀ is attributed to recombination of the photo generated carriers in a space charge region or recombination of at a pn junction interface. Accordingly, it is thought that the main cause of the low efficiency of the solar cell using the Ib-rich chalcopyrite absorber layer subjected to the KCN etching is that recombination of the photo generated carriers in the vicinity of junction interface is large.

As mentioned above, in a single layer of the chalcopyrite p-type semiconductor film, high carrier transport properties in which electric properties are good and the PL and CL with a narrow half width are obtained is expected; on the other hand, a high conversion efficiency has not been attained even if the chalcopyrite p-type semiconductor film is applied to the absorber layer to fabricate the solar cell because recombination of the photo generated carriers at a junction interface with an n-type semiconductor layer is high, and it is difficult to obtain a high V_{OC}.

### Solution to Problem

In order to achieve the object above, the solar cell according to the present invention comprises a first absorber layer that is a p-type semiconductor layer containing a Ib group element, a IIIb group element, and a VIb group element, and including a peak of photoluminescence or cathodoluminescence whose half width is not less than 1 meV and not more than 15 meV in a photoluminescence spectrum or a cathodoluminescence spectrum; and a second absorber layer containing a Ib group element, a IIIb group element, and a VIb group element on the first absorber layer, a composition ratio of the Ib group element to the IIIb group element being not less than 0.1 and less than 1.0.

According to the present invention above, the open-circuit voltage can be increased, resulting in increase in the conversion efficiency, compared to the conventional solar cell including only the p-type semiconductor layer including a peak of luminescence whose half width is not less than 1 meV and not more than 15 meV in a photoluminescence spectrum or a cathodoluminescence spectrum as the absorber layer.

The present inventors think that the second absorber layer having the Ib-poor composition is formed on the first p-type absorber layer that is the p-type semiconductor layer including a peak of luminescence whose half width is not less than 1 meV and not more than 15 meV in a photoluminescence spectrum or a cathodoluminescence spectrum, and an n-type semiconductor layer is formed thereon; thereby, recombination of the photo generated carriers at the pn junction interface can be reduced, and as a result, the advantageous effects of the invention are obtained. A specific reason will be shown below.

FIG. 6 shows a schematic view of a band structure of the conventional solar cell including only the p-type semiconductor layer including a peak of luminescence whose half width is not less than 1 meV and not more than 15 meV in a photoluminescence spectrum or a cathodoluminescence spectrum as the absorber layer, and FIG. 7 shows a schematic view of an example of a band structure of the solar cell obtained in the present invention. As shown in FIG. 7, the bandgap of the surface of the absorber layer can be enlarged by the second absorber layer. This is because a valence band minimum energy position (E_{V}) is lower than that of the first absorber layer. Thereby, this region serves as a barrier layer against injection of the holes at the junction interface with the n-type semiconductor layer, and recombination of the photo generated carriers at the junction interface can be reduced; as a result, the advantageous effects of the invention are obtained.

In the present invention above, it is preferable that the composition ratio of the Ib group element to the IIIb group element contained in the first absorber layer is 1.0. At a ratio of Ib group element/IIIb group element more than 1.0, segregation of a secondary phase conductive Ibx group-VIb group compound occurs, and the solar cell device is short-circuited; thus, the properties are likely to be deteriorated, and the advantageous effects of the invention tend to be reduced. At a ratio less than 1.0, the fluctuation of the energy level described above is increased, and the advantageous effects of the invention tend to be reduced.

In the present invention above, it is preferable that the Ib group element and IIIb group element contained in the second absorber layer are the same as those contained in the first absorber layer. Thereby, the advantageous effects of the invention are remarkable.

In the present invention above, it is preferable that the Ib group element contained in the first absorber layer and the second absorber layer is Cu. Thereby, the advantageous effects of the invention are more remarkable.

In the present invention above, it is preferable that a thickness of the second absorber layer formed on the first absorber layer is in the range of not less than 1 nm and not more than 100 nm. Thereby, the advantageous effects of the invention are further remarkable.

If is preferable that 1<k<2 when excitation light dependence is measured in measurement of the photoluminescence, wherein a relationship between intensity of excitation light Iₑₓ^{k} and intensity of photoluminescence I_{N}, is represented by the following expression (2):

[Expression 2]

I_{PL}∝Iₑₓ^{k} (Expression 2)

Thereby, the advantageous effects of the invention are remarkable.

It is preferable that a step of producing the first absorber layer comprises a step of performing Ib-rich growth, and subsequently removing a Ib group-VIb group compound excessively precipitated. Thereby, the conductive secondary phase Ib group-VIb group compound can be removed from the absorber layer, and the advantageous effects of the invention are remarkable.

It is preferable that the second absorber layer is formed by one method selected from a vacuum evaporation method and a sputtering method. Thereby, the second absorber layer having a uniform composition and film thickness distribution in which impurities components that cause deterioration of the properties are little can be formed easily in a large area; for this reason, the advantageous effects of the invention are remarkable.

It is preferable that in addition to the one method selected from a vacuum evaporation method and a sputtering method, the second absorber layer is formed by performing a heating treatment at a subsequent step. Thereby, an amount of the Ib group element to be diffused from the first p-type absorber layer to the second absorber layer can be precisely controlled, and the value of the film thickness of the second absorber layer can be precisely controlled; for this reason, the advantageous effects of the invention are remarkable.

### Advantageous Effects of Invention

According to the present invention, the solar cell, and the process for producing a solar cell can be provided in which the open-circuit voltage can be increased, and as a result, the conversion efficiency can be increased compared to the conventional solar cell including the chalcopyrite p-type semiconductor film including a peak of luminescence whose half width is not less than 1 meV and not more than 15 meV in a photoluminescence spectrum or a cathodoluminescence spectrum as the absorber layer.

### BRIEF DESCRIPTION OF DRAWINGS

FIG. 1 is a schematic sectional view of a conventional solar cell including a chalcopyrite p-type semiconductor film including a peak of luminescence whose half width is not less than 1 meV and not more than 15 meV in a photoluminescence spectrum or a cathodoluminescence spectrum as a absorber layer.

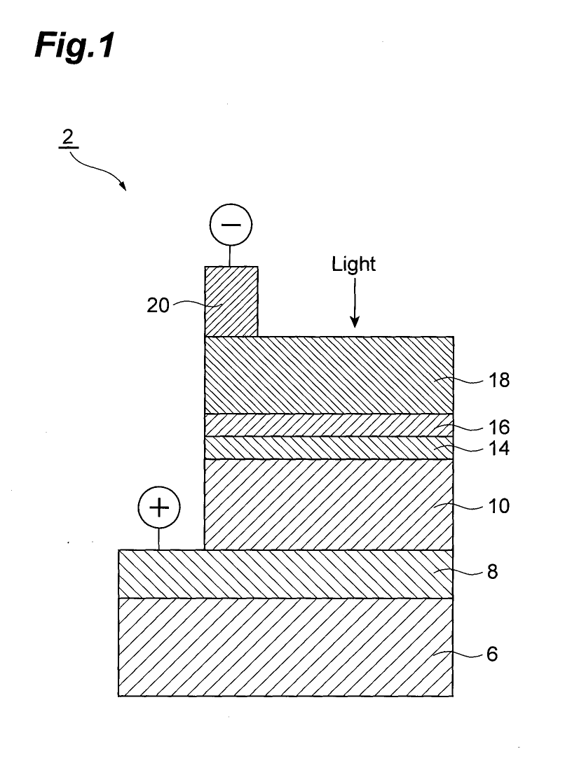

FIG. 2 is a schematic sectional view of a solar cell according to one embodiment of the present invention.

FIG. 3 is an equilibrium phase diagram between Cu₂Se and In₂Se₃.

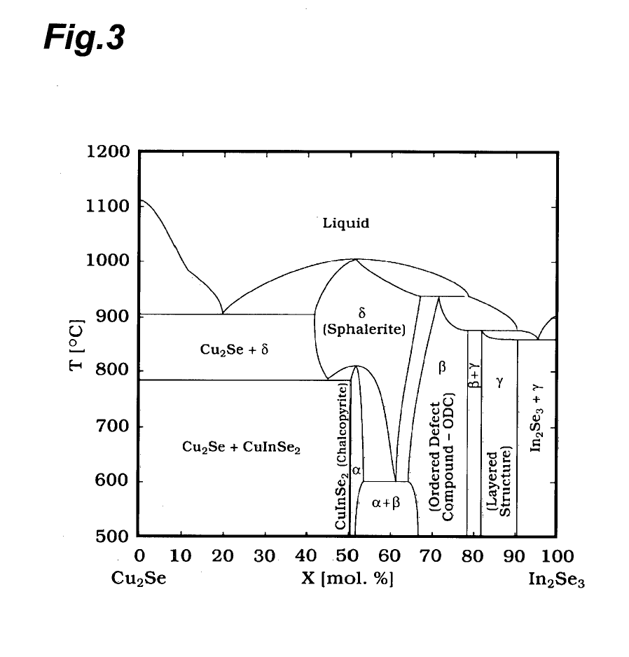

FIG. 4 shows a simulation result of current-voltage properties in the case where a single diode model is assumed in a pn junction solar cell, and a reverse saturation current density j₀ is used as a parameter.

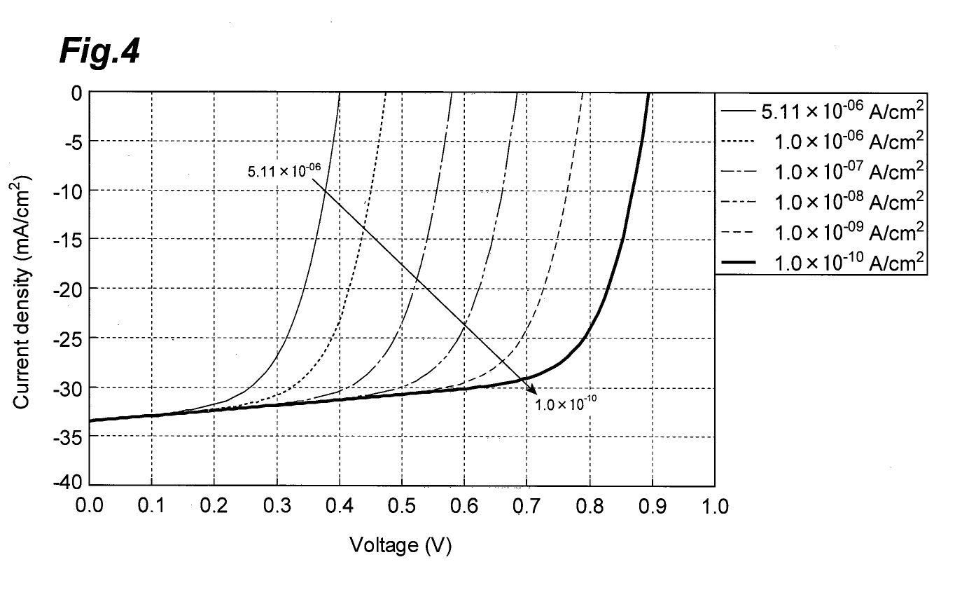

FIG. 5 shows a simulation result of current-voltage properties in the case where a single diode model is assumed in a pn junction solar cell, and a parallel resistance component R_{P} is used as a parameter.

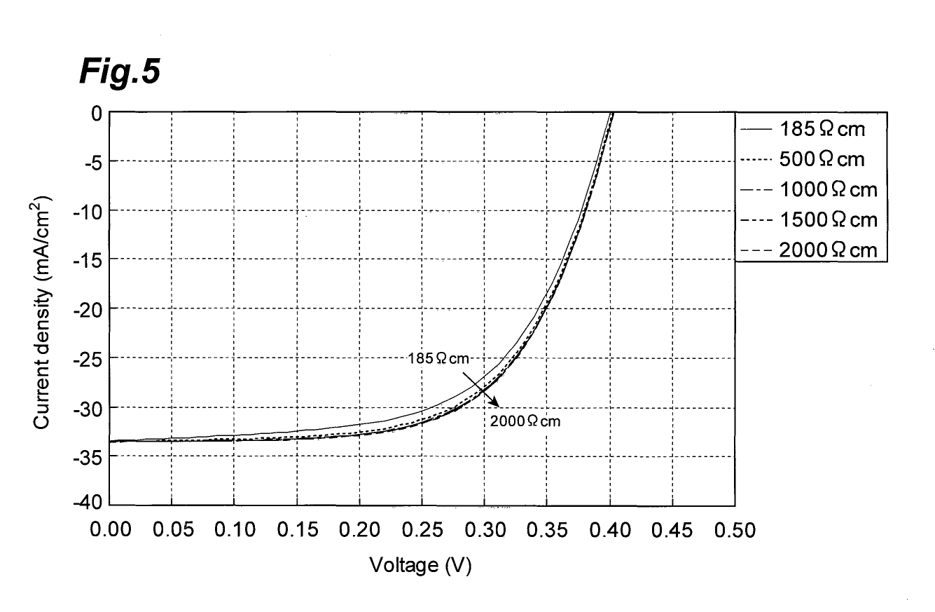

FIG. 6 is a schematic view of a band structure of the conventional solar cell including the chalcopyrite p-type semiconductor film including a peak of luminescence whose half width is not less than 1 meV and not more than 15 meV in a photoluminescence spectrum or a cathodoluminescence spectrum as the absorber layer.

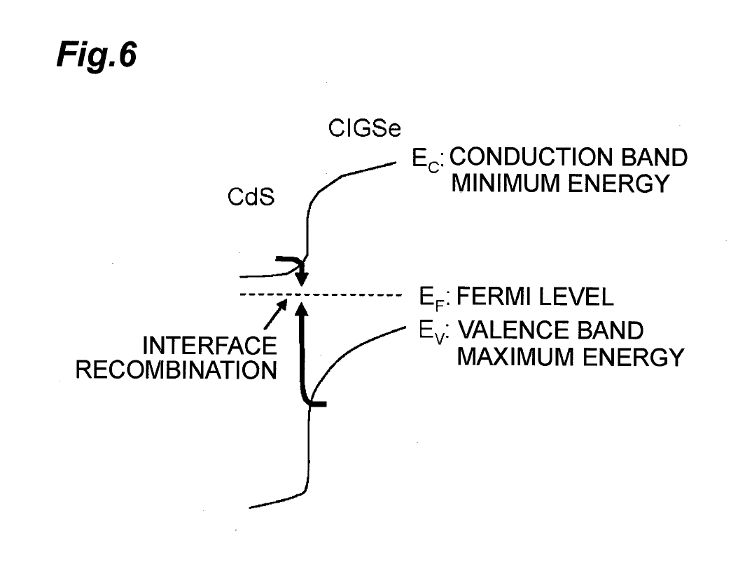

FIG. 7 is a schematic view of an example of a band structure of the solar cell obtained in the present invention.

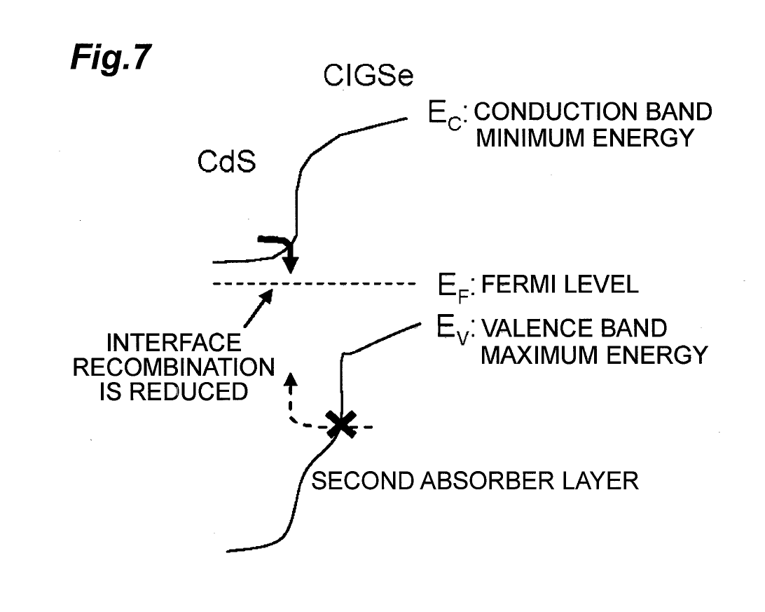

### DESCRIPTION OF EMBODIMENTS

Hereinafter, in reference with the drawings, one suitable embodiment according to the present invention will be described in detail. In the drawings, the same or identical components will be given the same reference numerals. Moreover, positional relations of top, bottom, left, and right are as shown in the drawings. Moreover, in the case where explanation is duplicated the explanation thereof will be omitted.

(Solar Cell)

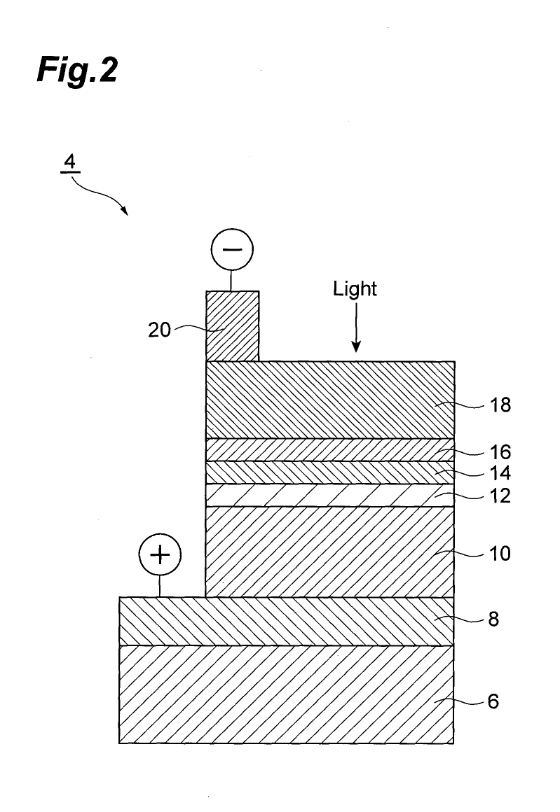

As shown in FIG. 2, a solar cell 4 according to the present embodiment is a thin film type solar cell including: a soda-lime glass 6, a back electrode layer 8 formed on the soda-lime glass 6, a first p-type absorber layer 10 formed on the back electrode layer 8, a second absorber layer 12 formed on the first p-type absorber layer 10, an n-type semiconductor layer 14 formed on the second absorber layer 12, a semi-insulating layer 16 formed on the n-type semiconductor layer 14, a window layer 18 (transparent conductive layer) formed on the semi-insulating layer 16, and an upper electrode 20 (extraction electrode) formed on the window layer 18.

The first p-type absorber layer 10 is a p-type compound semiconductor layer composed of a Ib group element such as Cu, Ag, or Au, a IIIb group element such as In, Ga, or Al, and further a VIb group element such as O, S, Se, or Te.

The second absorber layer 12 formed on the first p-type absorber layer 10 is a layer composed of a Ib group element such as Cu, Ag, or Au, a IIIb group element such as In, Ga, or Al, and further a VIb group element such as O, S, Se, or Te.

The photoluminescence spectrum or the cathodoluminescence spectrum of the first p-type absorber layer 10 includes a peak of luminescence whose half width is not less than 1 meV and not more than 15 meV. The spectrum of the luminescence is observed at a low temperature of 10 K (kelvin) or less.

If the half width of the photoluminescence spectrum or the cathodoluminescence spectrum obtained from the first p-type absorber layer 10 is more than 15 meV, carrier transport properties of the p-type absorber layer is unintendedly deteriorated, and the advantageous effects of the invention cannot be obtained.

If the half width of the photoluminescence spectrum or the cathodoluminescence spectrum obtained from the first p-type absorber layer 10 is less than 1 meV, detection of the spectrum is difficult, and the spectrum cannot be distinguished from a noise.

Hereinafter, the ratio of the content of the Ib group element (atomic %) to that of the IIIb group element (atomic %) in the first p-type absorber layer 10 or second absorber layer 12 will be written as the ratio of Ib group element/IIIb group element.

The second absorber layer 12 formed on the first p-type absorber layer 10 including the luminescence is a layer composed of a Ib group element such as Cu, Ag, or Au, a IIIb group element such as In, Ga, or Al, and further a VIb group element such as O, S, Se, or Te. The ratio of Ib group element/IIIb group element in the second absorber layer 12 is not less than 0.1 and less than 1.0. If the ratio of Ib group element/IIIb group element contained in the second absorber layer is less than 0.1, a compound is formed only between the IIIb group element and the VIb group element to prevent absorption of the light and carrier transport, leading to deterioration in the properties. If the ratio of Ib group element/IIIb group element is more than 1.0, a conductive compound is formed between the Ib group element and the VIb group element to deteriorate the properties. Moreover, because the bandgap energy is unintendedly the same as that of the first p-type absorber layer 10, the second absorber layer 12 does not act as a barrier region against hole injection, therefore the advantageous effects of the invention cannot be obtained.

It is preferable that the ratio of Ib group element/IIIb group element in the first p-type absorber layer 10 is 1.0. At a ratio of Ib group element/IIIb group element more than 1.0, segregation of a secondary phase conductive Ibx group-VIb group compound occurs, and the solar cell device is short-circuited; thus, the properties are likely to be deteriorated, and the advantageous effects of the invention tend to be reduced. At a ratio less than 1.0, the fluctuation of the energy level described above is increased, and the advantageous effects of the invention tend to be reduced.

It is preferable that the Ib group element and IIIb group element contained in the second absorber layer 12 formed on the first p-type absorber layer 10 are the same as the Ib group element and IIIb group element contained in the first p-type absorber layer 10. Moreover, it is preferable that in the case where a plurality of Ib group elements is used for the respective layers, the ratio thereof is the same. Similarly, it is preferable that in the case where a plurality of IIIb group elements is used for the respective layers, the ratio thereof is also the same. Thereby, the advantageous effects of the invention are easily obtained.

In the case where the Ib group element and IIIb group element contained in the second absorber layer 12 formed on the first p-type absorber layer 10 are not the same as those contained in the first p-type absorber layer 10, the bandgap energy of the first p-type absorber layer 10 is different from that of the second absorber layer 12. This is mainly because the position of the conduction band minimum energy E_{C} is changed. In the case where the position of the conduction band minimum energy E_{C} of the second absorber layer 12 is smaller than that of the first p-type absorber layer 10, recombination of injected holes and injected electrons is unintendedly increased through the defect level of the junction interface or the interface between the first p-type absorber layer 10 and second absorber layer 12 to reduce the open-circuit voltage. On the other hand, in the case where the position of the conduction band minimum energy E_{C} of the second absorber layer 12 is larger than that of the first p-type absorber layer 10, this difference of the energy acts as a barrier against the photo generated carriers. Thereby, the number of the carriers to be extracted is reduced to reduce the short-circuit current density J_{SC}.

In the case where the Ib group element contained in the first p-type absorber layer 10 and the second absorber layer 12 is Cu, the bandgap energy of the two layers can be adjusted in a wide range of approximately 1.0 eV to approximately 3.5 eV, and it is preferable. In the case where the VIb group element contained in the first p-type absorber layer 10 is Se, it is preferable that the III group element is an element selected from In, Ga, a combination of In and Ga, or that of In and Al. Thereby, the bandgap energy can be adjusted between approximately 1.0 eV and approximately 1.8 eV, which is the bandgap energy suitable for the absorber layer for the solar cell. In the case where the VIb group element contained in the first p-type absorber layer 10 is S, it is preferable that the IIIb group element is In or a combination of In and Ga. Thereby, the bandgap energy can be adjusted between approximately 1.0 eV and approximately 1.8 eV, which is the bandgap energy suitable for the absorber layer for the solar cell.

It is preferable that the thickness of the second absorber layer formed on the first p-type absorber layer 10 is not less than 1 nm and not more than 100 nm. At a thickness less than 1 nm, function as a barrier layer for hole injection is reduced by a tunneling phenomenon. Moreover, formation of the second absorber layer is difficult because it is excessively thin. At a thickness more than 100 nm, the properties tend to be deteriorated because recombination of the carries occurs in the second absorber layer.

It is preferable that 1<k<2 when the excitation light intensity dependence or excited electron beam intensity dependence is measured in measurement of the photoluminescence in the first p-type absorber layer 10, wherein a relationship between intensity of excitation light or intensity of an excited electron beam Iₑₓ^{k} and intensity of photoluminescence Iₙ is represented by the following expression (2):

[Expression 3]

I_{PL}∝Iₑₓ^{k} (Expression 2)

The value of k in measurement of the photoluminescence designates the origin of the luminescence, and the luminescence whose k value is in the range is excitonic luminescence. The excitonic luminescence is obtained from a thin film in which crystallinity is extremely good. The thin film in which crystallinity is extremely good has high carrier transport properties. Accordingly, high conversion efficiency is obtained by using a film that can obtain photoluminescence whose k value is in the range for the absorber layer.

(Process for Producing Solar Cell)

In the present embodiment, first, the back electrode layer 8 is formed on the soda-lime glass 6. The back electrode layer 8 is usually a metallic layer composed of Mo. Examples of a method for forming the back electrode layer 8 include sputtering using an Mo target.

After the back electrode layer 8 is formed on the soda-lime glass 6, the first p-type absorber layer 10 is formed on the back electrode layer 8. Examples of a method for forming the first p-type absorber layer 10 include a one-stage simultaneous vacuum evaporation method, a two-stage vacuum evaporation method, a solid phase selenization method, or a gas phase selenization method.

It is preferable that the first p-type absorber layer 10 is formed such that the Ib group-VIb group composition may be once at a value more than 1.0, namely, the Ib-rich composition.

For example, in the case where the one-stage vacuum evaporation method is used, it is preferable that the evaporation pressure (flux) of the IIIb group is 7 times or less the evaporation pressure of the Ib group. At a value more than 7 times the evaporation pressure (flux) of the Ib group, the Ib-rich composition is not obtained, and the advantageous effects of the invention are reduced.

For example, in the case where the two-stage vacuum evaporation method is used, the IIIb group element and the VIb group element are simultaneously deposited at a first stage. At a second stage, the Ib group element and the VIb group element are simultaneously deposited, and formation of the film is terminated at a point of time when the Ib-rich composition is obtained.

For example, in the case where the solid phase selenization (or sulfurization) method or the gas phase selenization (or sulfurization) method is used, a film of a Ib group-VIb group element compound such as Cu₂Se, Cu₂S, Ag₂Se, and Ag₂S or a film of a Ib group element such as Cu and Ag, and a film of a IIIb group-VIb group element compound such as In₂Se₃, In₂S₃, Ga₂Se₃, Ga₂S₃, Al₂Se₃, and Al₂S₃ or a film of a IIIb group element such as In, Ga, and Al are formed as a precursor. Subsequently, a heat treatment is performed under a solid Se, solid S, or hydrogen selenide atmosphere or an atmosphere containing hydrogen sulfide to form the first p-type absorber layer 10. A vacuum evaporation method, a sputtering method, an electrodeposition method, a printing method, and the like are used for formation of the precursor. According to the ratio of the film thickness of the Ib group-VIb group element compound film or Ib group element film to that of the IIIb group-VIb group element compound film or IIIb group element film, adjustment is performed so as to obtain the Ib-rich composition.

It is preferable that the ratio of Ib group element/IIIb group element of the first p-type absorber layer 10 produced by the methods once reaches the range of 1.1 to 1.6. Thereby, the advantageous effects of the invention are remarkable. At a ratio less than 1.1, the film whose carrier transport properties are relatively small is obtained, and the advantageous effects of the invention are small. At a ratio more than 1.6, the conductive Ib group-VI group compound usually precipitated only on the surface of the film is also precipitated at a grain boundary in the film; it is difficult to completely remove the conductive Ib group-VI group compound at a subsequent step, and the advantageous effects of the invention tend to be reduced.

After formation of the first p-type absorber layer 10, it is preferable that an excessive Ib group-VIb group compound is removed. Examples of a method for removing a secondary phase Ib group-VIb group compound include an etching treatment by immersion in a potassium cyanide aqueous solution, or a method by electrochemical etching and a heat treatment under a foaming gas atmosphere. Alternatively, a method may be used in which the IIIb group and the VIb group are simultaneously deposited and reacted with an excessive Ib group-VIb group compound to consume the excessive Ib group-VIb group compound, thereby to form a Ib group-IIIb group-VIb group compound. By these methods, the conductive Ib-VIb group compound, for example, a secondary phase such as CuxSe, CuxS, AgxSe, and AgxS can be removed from the first p-type absorber layer 10, and the advantageous effects of the invention are remarkable.

It is preferable that the ratio of Ib group/IIIb group is 1.0 in the layer after the secondary phase is removed by the method, namely the layer finally used as the first p-type absorber layer 10. By using the method, the layer with high carrier transport properties containing no conductive secondary phase Ib group-VIb group compound, and a photoluminescence or a cathodoluminescence spectrum with a narrow half width can be formed, and good conversion efficiency is easily obtained by using this layer for the first p-type absorber layer 10 of the solar cell according to the present invention.

After formation of the first p-type absorber layer 10, the second absorber layer 12 is formed on the first p-type absorber layer 10. Examples of a method for forming the second absorber layer 12 include the following methods.

In a first method, the second absorber layer 12 is formed on the first p-type absorber layer 10 by the vacuum evaporation method. As a specific example, a laminate (hereinafter, written as a “substrate”) including the soda-lime glass 6, the back electrode layer 8, and the first p-type absorber layer 10 is placed within a growth chamber, and the growth chamber is evacuated. Subsequently, while the substrate is heated, the IIIb group element and the VIb group element are simultaneously deposited.

In the first method, the second absorber layer 12 is formed by reaction of the Ib group element diffused from the first p-type absorber layer 10 to the surface direction with the deposited IIIb group element and VIb group element.

In the first method, the composition and the film thickness can be properly controlled within the range by adjusting the amount of evaporation (flux) of each element, which is supplied into the growth chamber.

In the first method, it is preferable that the temperature of the substrate is 100 to 550° C. If the temperature of the substrate is excessively low, the reaction of the IIIb group element with the VIb group element is hardly made, a desired composition and film thickness of the second absorber layer 12 tend to be hardly obtained. On the other hand, if the temperature of the substrate is excessively high, the substrate tends to be softened to deform or be dissolved, and the film forming rate tends to be remarkably reduced. These tendencies can be suppressed by controlling the temperature of the substrate in the range above.

In the first method, it is more preferable that the temperature of the substrate is 250 to 350° C. If the second absorber layer 12 is formed at a temperature not more than that in this range, the compound tends to be formed only between the IIIb group element and the VIb group element to prevent absorption of the light and transport of the carriers, leading to deterioration in the properties. Moreover, the crystallinity of the second absorber layer 12 is deteriorated, and good properties tend to be not obtained. If the second absorber layer 12 is formed at a temperature not less than that in this range, excessive diffusion of the Ib group element from the first p-type absorber layer 10 to the surface direction tends to occur to reduce the ratio of Ib group/IIIb group element of the first p-type absorber layer 10, and the ratio of Ib group/IIIb group element of the second absorber layer 12 tends to be increased; accordingly, control of the composition is relatively difficult.

In the first method, in the case where the temperature of the substrate is 350 to 550° C., it is preferable that in addition to the IIIb group element and the VIb group element, the Ib group element is deposited together. Thereby, excessive diffusion of the Ib group element from the first p-type absorber layer 10 to the second absorber layer 12 can be suppressed. In the case where excessive diffusion of the Ib group element from the first p-type absorber layer 10 to the surface direction occurs, the ratio of Ib group/IIIb group element of the first p-type absorber layer 10 tends to be reduced, and the ratio of Ib group/IIIb group element of the second absorber layer 12 tends to be increased; accordingly, control of the composition is relatively difficult. Moreover, in the case where excessive diffusion of the Ib group element from the first p-type absorber layer 10 to the film surface direction, namely, to the second absorber layer 12 occurs, the half width of the photoluminescence or the cathodoluminescence spectrum obtained from the first p-type absorber layer tends to be increased. Thereby, carrier transport properties are easily deteriorated. This tendency can be suppressed by adding the Ib group element during deposition in order to form the second absorber layer 12.

It is preferable that the IIIb group element used in the first method is the same as that contained in the first p-type absorber layer 10. In the first method, in the case where the Ib group elements are used in combination, it is preferable that the Ib group elements are the same as those contained in the first p-type absorber layer 10. Thereby, the advantageous effects of the invention are remarkable.

In a second method, the second absorber layer 12 is formed on the first p-type absorber layer 10 by the sputtering method. As a specific example, a laminate (hereinafter, written as a “substrate”) including the soda-lime glass 6, the back electrode layer 8, and the first p-type absorber layer 10 and a sputtering target composed of a IIIb group-VIb group compound are placed within an sputtering apparatus, and the sputtering apparatus is evacuated. Subsequently, while the substrate is heated, the target is sputtered to form the second absorber layer 12.

In the second method, the composition of each element in the sputtering target placed within the sputtering apparatus can be properly controlled within the range by adjusting the composition thereof.

In the second method, it is preferable that the temperature of the substrate is 100 to 550° C. If the temperature of the substrate is excessively low, the reaction of the IIIb group element with the VIb group element hardly occurs, and a desired composition and film thickness of the second absorber layer 12 tend to be not obtained. On the other hand, if the temperature of the substrate is excessively high, the substrate tends to be softened to deform or be dissolved, and the film forming rate tends to be remarkably reduced. These tendencies can be suppressed by controlling the temperature of the substrate in the range above.

In the second method, it is more preferable that the temperature of the substrate is 250 to 350° C. If the second absorber layer 12 is formed at a temperature not more than that in this range, the compound tends to be formed only between the IIIb group element and the VIb group element to prevent absorption of the light and transport of the carriers, leading to deterioration in the properties. Moreover, the crystallinity of the second absorber layer 12 is deteriorated, and good properties tend to be not obtained. If the second absorber layer 12 is formed at a temperature not less than that in this range, in the case where excessive diffusion of the Ib group element from the first p-type absorber layer 10 to the surface direction occurs, the ratio of Ib group/IIIb group element of the first p-type absorber layer 10 tends to be reduced, and the ratio of Ib group/IIIb group element of the second absorber layer 12 tends to be increased; accordingly, control of the composition is relatively difficult.

In the second method, in the case where the temperature of the substrate is 350 to 550° C., it is preferable that a sputtering target containing the Ib group element in addition to the IIIb group element and the VIb group element is used as the sputtering target. Thereby, excessive diffusion of the Ib group element from the first p-type absorber layer 10 to the second absorber layer 12 can be suppressed. In the case where excessive diffusion of the Ib group element from the first p-type absorber layer 10 occurs, the half width of the photoluminescence or the cathodoluminescence spectrum obtained from the first p-type absorber layer tends to be increased. Thereby, carrier transport properties are easily deteriorated. This tendency can be suppressed by adding a Ib group element to the target.

In the second method, it is preferable that the IIIb group element contained in the sputtering target is the same as that contained in the first p-type absorber layer 10. In the second method, in the case where the Ib group element is added to the sputtering target, it is preferable that the Ib group element is also the same as that contained in the first p-type absorber layer 10. Thereby, the advantageous effects of the invention are remarkable.

In a third method, by a vacuum evaporation method or sputtering method using an apparatus with the same configuration as that in the first method or second method, a layer containing the IIIb group and VIb group elements (hereinafter, written as a “surface precursor layer”) is formed, and subjected to a heat treatment, thereby to form the second absorber layer 12.

In the third method, it is preferable that the heat treatment is performed under an atmosphere containing a solid VIb group element, hydrogen selenide, or hydrogen sulfide. If the first p-type absorber layer 10 is heated, the VIb group element tends to be eliminated to change the p-type to the n-type. This tendency can be suppressed by performing the heat treatment under an atmosphere containing a solid VIb group element, hydrogen selenide, or hydrogen sulfide.

In the third method, it is preferable that the temperature during formation of the film by the vacuum evaporation method or sputtering method is not more than 200° C. Thereby, the thickness of the second absorber layer is easily controlled.

In the third method, it is preferable that the temperature of the heat treatment is 250 to 550° C. Further, it is more preferable that the temperature of the heat treatment is 250 to 350° C. If the temperature of the heat treatment is excessively low, the surface precursor layer tends to remain. If the temperature of the heat treatment is excessively high, the substrate tends to be softened to deform, or be dissolved. Moreover, at a temperature of 350 to 550° C. at which the substrate is not softened or be dissolved, excessive diffusion of the Ib group element from the first p-type absorber layer 10 to the surface direction easily occurs. The ratio of Ib group/IIIb group element of the first p-type absorber layer 10 tends to be reduced, and the ratio of Ib group/IIIb group element of the second absorber layer 12 tends to be increased; accordingly, control of the composition is relatively difficult. In the case where excessive diffusion of the Ib group element from the first p-type absorber layer 10 occurs, the half width of the photoluminescence or the cathodoluminescence spectrum obtained from the first p-type absorber layer tends to be increased. Thereby, carrier transport properties are easily deteriorated. These tendencies can be suppressed by controlling the temperature of the substrate within the range above.

In the third method, in the case where the temperature of the heat treatment is 350 to 550° C., it is preferable that the Ib group element is contained in addition to the IIIb group element and the VIb group element during formation of the film by the vacuum evaporation method or the sputtering method. Thereby, excessive diffusion of the Ib group element from the first p-type absorber layer 10 to the second absorber layer 12 can be suppressed. In the case where excessive diffusion of the Ib group element from the first p-type absorber layer 10 occurs, the half width of the photoluminescence or the cathodoluminescence spectrum obtained from the first p-type absorber layer tends to be increased. Thereby, carrier transport properties are easily deteriorated. This tendency can be suppressed by adding the Ib group element to the target.

In the third method, it is preferable that the IIIb group element used in the vacuum evaporation method or the IIIb group element contained in the sputtering target is the same as that contained in the first p-type absorber layer 10. In the third method, in the case where the Ib group element is added to a deposition source used in vacuum evaporation or the sputtering target, it is preferable that the Ib group element is also the same as that contained in the first p-type absorber layer 10. Thereby, the advantageous effects of the invention are remarkable.

In the present embodiment, forming conditions are set such that the ratio of Ib group element/IIIb group element contained in the second absorber layer 12 may be not less than 0.1 and less than 1.0.

In the case of the first method, the composition of the second absorber layer 12 can be properly controlled in the range by adjusting the temperature of the substrate and the flux amount of each element.

In the case of the second method, the composition of the second absorber layer 12 can be properly controlled in the range by adjusting the temperature of the substrate and the composition ratio of each element contained in the target.

In the case of the third method/process, the composition of the second absorber layer 12 can be properly controlled in the range by the same method as the first method and the second method.

In the present embodiment, it is preferable that the forming conditions are set such that the thickness of the second absorber layer 12 may be not less than 1 nm and not more than 100 nm.

In the case of the first method, the thickness of the second absorber layer 12 can be properly controlled in the range by adjusting the temperature of the substrate, the flux amount of each element, and the film forming time.

In the case of the second method, the thickness of the second absorber layer 12 can be properly controlled in the range by adjusting the temperature of the substrate, the distance between the substrate and the target, a sputtering electric power, and the film forming time.

In the case of the third method, the thickness of the second absorber layer 12 can be controlled as appropriate in the range by the same method as the first method and the second method. In addition to that, by adjusting the temperature of the heat treatment and the time of the heat treatment, the thickness of the second absorber layer 12 can be properly controlled in the range.

After formation of the second absorber layer 12, the n-type semiconductor layer 14 is formed on the second absorber layer 12. Examples of the n-type semiconductor layer 14 include a CdS layer, a Zn(S,O,OH) layer, a ZnMgO layer, or a Zn(Oₓ,S₁₋ₓ) layer (x is a positive real number less than 1). The CdS layer and the Zn(S,O,OH) layer can be formed by a solution growth method (Chemical Bath Deposition). The ZnMgO layer can be formed by a chemical vapor deposition method such as MOCVD (Metal Organic Chemical Vapor Deposition) or sputtering. The Zn(Oₓ,S₁₋ₓ) layer can be formed by an ALD method (Atomic layer deposition) and the like.

After formation of the n-type semiconductor layer 14, the semi-insulating layer 16 is formed on the n-type semiconductor layer 14, the window layer 18 is formed on the semi-insulating layer 16, and the upper electrode 20 is formed on the window layer 18.

Examples of the semi-insulating layer 16 include a ZnO layer and ZnMgO layer.

Examples of the window layer 18 include ZnO:Al, ZnO:B, ZnO:Ga, and ITO.

The semi-insulating layer 16 and the window layer 18 can be formed by a chemical vapor deposition method such as MOCVD (Metal Organic Chemical Vapor Deposition) or sputtering.

The upper electrode 20 is composed of a metal such as Al or Ni. The upper electrode 20 can be formed by thermal evaporation, electron beam deposition, or sputtering. Thereby, the thin film type solar cell 4 is obtained. An anti-reflective layer may be formed on the window layer 18. Examples of the anti-reflective layer include MgF₂, TiO₂, and SiO₂. The window layer 18 can be formed by thermal evaporation, electron beam deposition, a sputtering method, or the like.

As describe above, one suitable embodiment according to the present invention has been described in detail, but the present invention will not be limited to the embodiment above. For example, the first p-type absorber layer 10 and the second absorber layer 12 may be formed by a printing method, an electrodeposition method, a chemical solution growth method, a gas phase selenization method, a gas phase sulfurization method, a solid phase selenization method, a solid phase sulfurization method, or a method in combination thereof. The solar cell 4 according to the embodiment can be produced.

### EXAMPLES

Hereinafter, the present invention will be more specifically described based on Examples and Comparative Examples, but the present invention will not be limited to Examples below.

### Example 1

A soda-lime glass with a length of 10 cm×a width of 10 cm×a thickness of 1 mm was washed, and dried; then, a film-like back electrode composed of Mo by itself was formed on the soda-lime glass by a DC sputtering method. The film thickness of the back electrode was 1 μm.

In Example 1, a “substrate” means a target object for deposition or an object to be measured at each step.

Subsequently, formation of a first p-type absorber layer was performed by a vacuum evaporation method using a Physical Vapor deposition (physical vapor deposition, hereinafter, referred to as PVD) machine. The relationship between the flux ratio of each raw material element and the compositions contained in the film to be obtained was measured in advance before formation of the film at each step by the PVD machine, thereby to adjust the compositions of the film. The flux of each element was properly changed by adjusting the temperature of each K cell. At the step of forming the first p-type absorber layer in Example 1, the flux of each element was set such that the Ib group/IIIb group composition ratio immediately after formation of the film might be 1.01.

The back electrode formed on the soda-lime glass was placed within the chamber of the PVD machine, and the inside of the chamber was evacuated. The ultimate pressure within the vacuum chamber was 1.0×10⁻⁸ torr.

Then, after the substrate was heated to 540° C. and the temperature was stabilized, the shutters of the respective K cells of Cu, In, and Se were opened to deposit Cu, In, and Se on the substrate. At a point of time when a layer with a thickness of approximately 2 μm was formed on the substrate by this deposition, the shutters of the respective K cells of Cu and In were closed. Then, after the substrate was cooled to 200° C., the shutter of the K cell of Se was closed to complete film formation of the first p-type semiconductor layer.

Analysis of the composition of each element that first p-type absorber layer contained was performed by energy dispersive X-ray spectroscopy (Energy Dispersive Spectroscopy: EDX). The Cu/In composition ratio in the first p-type absorber layer immediately after formation of the film was 1.01.

After formation of the first p-type absorber layer, the substrate was immersed in a potassium cyanide aqueous solution (10 wt %) for 5 minutes to remove a secondary phase Ib group-VIb group compound contained in the first p-type absorber layer.

Analysis of the composition of each element that first p-type absorber layer contained after the secondary phase removing treatment was performed by energy dispersive X-ray spectroscopy (Energy Dispersive X-Ray Spectroscopy: EDX). The Cu/In composition ratio of the p-type absorber layer after the secondary phase removing treatment was 0.98.

After the secondary phase removing treatment of the first p-type absorber layer, a second absorber layer was formed on the first p-type absorber layer by a vacuum evaporation method. Hereinafter, formation of the second absorber layer will be described.

The substrate was placed within the chamber of the PVD machine, and the inside of the chamber was evacuated. The ultimate pressure within the vacuum chamber was 1.0×10⁴ torr.

Then, after the substrate was heated to 300° C. and the temperature was stabilized, the shutters of the respective K cells of In and Se were opened to deposit In and Se on the substrate. At a point of time when a layer with a thickness of approximately 20 nm was formed on the substrate by this deposition, the shutter of the K cell of In was closed.

At the step, the second absorber layer composed of a compound of a Ib group element, a IIIb group element, and a VIb group element was formed by supply of the Ib group element diffused from the first p-type absorber layer to the film surface direction and the IIIb group element and VIb group element from the surface at the deposition step.

Then, after the substrate was cooled to 200° C., the shutter of the K cell of Se was closed to complete the film formation of the second absorber layer.

Analysis of the composition of each element that the second absorber layer contained was performed by auger electron spectroscopy (Auger Electron Spectroscopy: AES). The Cu/In composition ratio of the second absorber layer was 0.35.

After formation of the second absorber layer, a CdS buffer layer, which was an n-type semiconductor layer with a thickness of 50 nm, was formed on the second absorber layer by a chemical solution growth (Chemical Bath Deposition: CBD) method.

After formation of the n-type semiconductor layer, an i-ZnO layer (semi-insulating layer) with a thickness of 50 nm was formed on the n-type semiconductor layer. Subsequently, in the same chamber, a ZnO:Al layer (window layer) with a thickness of 0.5 μm was formed on the i-ZnO layer.

After formation of the window layer, measurement of the photoluminescence of the first p-type absorber layer was performed. An Ar ion laser having a wavelength of 514.5 nm was used for an excitation light source used for the measurement, and the substrate was cooled to 10 K (kelvin) by a cryostat at the time of measurement. The intensity of excitation light was changed from 1 mW/cm² to 100 mW/cm², and measurement of excitation light intensity dependence of the intensity of photoluminescence was performed.

In the photoluminescence spectrum obtained during measurement at 10 mW/cm², the half width of the luminescence with the narrowest half width was 15 meV.

The value of k was 1.03, wherein a relationship between the intensity of photoluminescence I_{PL} obtained from the measurement and the intensity of excitation light Iₑₓ^{k} was represented by the following expression (2):

[Expression 4]

I_{PL}∝Iₑₓ^{k} (Expression 2)

Further, a part of the substrate was cut, measurement of the cathodoluminescence of the first p-type absorber layer from the fracture surface was performed. The measurement was performed at 10 K (kelvin) similarly to that of the photoluminescence. In the cathodoluminescence spectrum obtained from the measurement, the half width of the luminescence with the narrowest half width was 15 meV.

After formation of the window layer, an upper electrode composed of Ni with a thickness of 50 nm and Al with a thickness of 1 μm thereon was formed on the ZnO:Al layer. The i-ZnO layer, the ZnO:Al layer, and the upper electrode each were formed by the sputtering method. Thereby, a thin film type solar cell of Example 1 was obtained.

The compound used for the first p-type absorber layer, the Ib group/IIIb group composition ratio in the first p-type absorber layer immediately after formation of the film, the Ib group/IIIb group composition ratio in the first p-type absorber layer after the secondary phase removing treatment, the half width value of the luminescence with the narrowest half width in the photoluminescence spectrum and cathodoluminescence spectrum of the first p-type absorber layer, the value of k in the measurement of the excitation light intensity dependence of the intensity of photoluminescence, and the secondary phase removing method are shown in Table 1.

The compound used for the second absorber layer, the ratio of the Ib group/IIIb group composition contained in the second absorber layer obtained in the AES measurement, the film thickness of the second absorber layer, the method for producing the second absorber layer, and the film forming temperature are shown in Table 2.

### Comparative Example 1

At the first p-type absorber layer film forming step, the flux was set such that the Ib group/IIIb group composition ratio in the first p-type absorber layer immediately after formation of the film might be 1.25. Moreover, the second absorber layer was not provided.

Except the description above, a solar cell of Comparative Example 1 was produced by the same method as that in Example 1.

The compound used for the first p-type absorber layer, the Ib group/IIIb group composition ratio in the first p-type absorber layer immediately after formation of the film, the Ib group/IIIb group composition ratio in the first p-type absorber layer after the secondary phase removing treatment, the half width value of the luminescence with the narrowest half width in the photoluminescence spectrum and the cathodoluminescence spectrum of the first p-type absorber layer, the value of k in the measurement of the excitation light intensity dependence of the intensity of photoluminescence, and the secondary phase removing method are shown in Table 1.

### Comparative Example 2

At the first p-type absorber layer film forming step, the flux was set such that the Ib group/IIIb group composition ratio in the first p-type absorber layer immediately after formation of the film might be 0.90. Moreover, the secondary phase removing treatment was not performed.

Except the description above, a solar cell of Comparative Example 2 was produced by the same method as that in Example 1.

The compound used for the first p-type absorber layer, the Ib group/IIIb group composition ratio in the first p-type absorber layer immediately after formation of the film, the Ib group/IIIb group composition ratio in the first p-type absorber layer after the secondary phase removing treatment, the half width value of the luminescence with the narrowest half width in the photoluminescence spectrum and the cathodoluminescence spectrum of the first p-type absorber layer, the value of k in the measurement of the excitation light intensity dependence of the intensity of photoluminescence, and the secondary phase removing method are shown in Table 1.

The compound used for the second absorber layer, the ratio of the Ib group/IIIb group composition contained in the second absorber layer obtained in the AES measurement, the film thickness of the second absorber layer, the method for producing the second absorber layer, and the film forming temperature are shown in Table 2.

### Examples 2 to 6

At the first p-type absorber layer film forming step, the flux was set such that the Ib group/IIIb group composition ratio in the first p-type absorber layer immediately after formation of the film might be a value shown in Table 1.

Except the description above, solar cells of Examples 2 to 6 were produced by the same method as that in Example 1.

The compound used for the first p-type absorber layer, the Ib group/IIIb group composition ratio in the first p-type absorber layer immediately after formation of the film, the Ib group/IIIb group composition ratio in the first p-type absorber layer after the secondary phase removing treatment, the half width value of the luminescence with the narrowest half width in the photoluminescence spectrum and the cathodoluminescence spectrum of the first p-type absorber layer, the value of k in the measurement of the excitation light intensity dependence of the intensity of photoluminescence, and the secondary phase removing method are shown in Table 1.

The compound used for the second absorber layer, the ratio of the Ib group/IIIb group composition contained in the second absorber layer obtained in the AES measurement, the film thickness of the second absorber layer, the method for producing the second absorber layer, and the film forming temperature are shown in Table 2.

TABLE 1

| | First p-type absorber layer | | | | | | | |
|---|---|---|---|---|---|---|---|---|
| | | | Ib group/IIlb | | | | | |
| | | | group | | | | | |
| | | | composition | | | | | |
| | | | ratio | | | | | |
| | | Ib group/IIb | of first | | | | | |
| | | group | p-type | | | | | |
| | | composition | absorber | | | | | |
| | | ratio | layer (after | | | | | |
| | | immediately | secondary | | | | | Secondary |
| | | after | phase | Photo- | Cathodo- | Photo- | | phase |
| | | formation | removing | luminescence | luminescence | luminescence | Production | removing |
| Table 1 | Material | of film | treatment) | half width (meV) | half width (meV) | k value | method | treatment |
| Comparative | CuInSe₂ | 1.25 | 1.03 | 7 | 7 | 1.20 | Vacuum | KCN |
| Example 1 | | | | | | | evaporation | etching |
| | | | | | | | method | |
| Comparative | CuInSe₂ | 0.90 | 0.90 | 40 | 40 | 0.80 | Vacuum | None |
| Example 2 | | | | | | | evaporation | |
| | | | | | | | method | |
| Example 1 | CuInSe₂ | 1.01 | 0.98 | 15 | 15 | 1.03 | Vacuum | KCN |
| | | | | | | | evaporation | etching |
| | | | | | | | method | |
| Example 2 | CuInSe₂ | 1.10 | 1.00 | 9 | 9 | 1.05 | Vacuum | KCN |
| | | | | | | | evaporation | etching |
| | | | | | | | method | |
| Example 3 | CuInSe₂ | 1.25 | 1.00 | 7 | 7 | 1.20 | Vacuum | KCN |
| | | | | | | | evaporation | etching |
| | | | | | | | method | |
| Example 4 | CuInSe₂ | 1.45 | 1.00 | 6 | 6 | 1.25 | Vacuum | KCN |
| | | | | | | | evaporation | etching |
| | | | | | | | method | |
| Example 5 | CuInSe₂ | 1.67 | 1.00 | 6 | 6 | 1.50 | Vacuum | KCN |
| | | | | | | | evaporation | etching |
| | | | | | | | method | |
| Example 6 | CuInSe₂ | 1.81 | 1.02 | 6 | 6 | 1.60 | Vacuum | KCN |
| | | | | | | | evaporation | etching |
| | | | | | | | method | |

TABLE 2

| | Second absorber layer | | | | |
|---|---|---|---|---|---|
| | | Ib group/IIIb | Film | | Film forming |
| | | group composition | thickness | | temperature |
| | Material | ratio | (nm) | Production method | (° C.) |
| Comparative | None | | | | |
| Example 1 | | | | | |
| Comparative | CuInSe₂ | 0.35 | 20 | Vacuum evaporation | 300 |
| Example 2 | | | | method In + Se | |
| Example 1 | CuInSe₂ | 0.35 | 20 | Vacuum evaporation | 300 |
| | | | | method In + Se | |
| Example 2 | CuInSe₂ | 0.35 | 20 | Vacuum evaporation | 300 |
| | | | | method In + Se | |
| Example 3 | CuInSe₂ | 0.35 | 20 | Vacuum evaporation | 300 |
| | | | | method In + Se | |
| Example 4 | CuInSe₂ | 0.35 | 20 | Vacuum evaporation | 300 |
| | | | | method In + Se | |
| Example 5 | CuInSe₂ | 0.35 | 20 | Vacuum evaporation | 300 |
| | | | | method In + Se | |
| Example 6 | CuInSe₂ | 0.35 | 20 | Vacuum evaporation | 300 |
| | | | | method In + Se | |

### Examples 7 to 11

### Comparative Example 3

At the first p-type absorber layer film forming step, the flux was set such that the Ib group/IIIb group composition ratio immediately after formation of the film might be a value shown in Table 3.

At the second absorber layer film forming step, the film forming temperature was set at a value shown in Table 4.

Except the description above, solar cells of Examples 7 to 11 and Comparative Example 3 were produced by the same method as that in Example 1.

The compound used for the first p-type absorber layer, the Ib group/IIIb group composition ratio in the first p-type absorber layer immediately after formation of the film, the Ib group/IIIb group composition ratio in the first p-type absorber layer after the secondary phase removing treatment, the half width value of the luminescence with the narrowest half width in the photoluminescence spectrum and the cathodoluminescence spectrum of the first p-type absorber layer, the value of k in the measurement of the excitation light intensity dependence of the intensity of photoluminescence, and the secondary phase removing method are shown in Table 3.

The compound used for the second absorber layer, the ratio of the Ib group/IIIb group composition contained in the second absorber layer obtained in the AES measurement, the film thickness of the second absorber layer, the method for producing the second absorber layer, and the film forming temperature are shown in Table 4.

### Examples 12 to 14

### Comparative Example 4

At the first p-type absorber layer film forming step, the flux was set such that the Ib group/IIIb group composition ratio immediately after formation of the film might be a value shown in Table 3.

After the secondary phase removing treatment of the first p-type absorber layer, a second absorber layer was formed on the first p-type absorber layer by the vacuum evaporation method.

The substrate was placed within the chamber of the PVD machine, and the inside of the chamber was evacuated. The ultimate pressure within the vacuum chamber was 1.0×10⁻⁸ torr.

Flux of each element was set in advance such that the Ib group/IIIb group composition ratio of the second absorber layer might be a value shown in Table 4.

Then, after the substrate was heated to the temperature shown in Table 4 and the temperature was stabilized, the shutters of the respective K cells of Cu, In, and Se were opened to deposit Cu, In, and Se on the substrate. At a point of time when a layer with a thickness of approximately 20 nm was formed on the substrate by this deposition, the shutters of the K cells of Cu and In were closed.

Then, after the substrate was cooled to 200° C., the shutter of the K cell of Se was closed to complete the film formation of the second absorber layer.

Except the description above, solar cells of Examples 12 to 14 and Comparative Example 4 were produced by the same method as that in Example 1.

The compound used for the first p-type absorber layer, the Ib group/IIIb group composition ratio in the first p-type absorber layer immediately after formation of the film, the Ib group/IIIb group composition ratio in the first p-type absorber layer after the secondary phase removing treatment, the half width value of the luminescence with the narrowest half width in the photoluminescence spectrum and the cathodoluminescence spectrum of the first p-type absorber layer, the value of k in the measurement of the excitation light intensity dependence of the intensity of photoluminescence, and the secondary phase removing method are shown in Table 3.

The compound used for the second absorber layer, the ratio of the Ib group/IIIb group composition contained in the second absorber layer obtained in the AES measurement, the film thickness of the second absorber layer, the method for producing the second absorber layer, and the film forming temperature are shown in Table 4.

TABLE 3

| | First p-type absorber layer | | | | | | | |
|---|---|---|---|---|---|---|---|---|
| | | | Ib group/ | | | | | |
| | | | IIIb group | | | | | |
| | | | composition | | | | | |
| | | Ib group/ | ratio of | | | | | |
| | | IIIb group | first p-type | | | | | |
| | | composition | absorber | | | | | |
| | | ratio | layer (after | | | | | |
| | | immediately | secondary | | | | | Secondary |
| | | after | phase | Photo- | Cathodo- | Photo- | | phase |
| | | formation | removing | luminescence | luminescence | luminescence | Production | removing |
| Table 3 | Material | of film | treatment) | half width (meV) | half width (meV) | k value | method | treatment |
| Comparative | CuInSe₂ | 1.20 | 1.00 | 8 | 8 | 1.10 | Vacuum | KCN |
| Example 3 | | | | | | | evaporation | etching |
| | | | | | | | method | |
| Example 7 | CuInSe₂ | 1.20 | 1.00 | 8 | 8 | 1.10 | Vacuum | KCN |
| | | | | | | | evaporation | etching |
| | | | | | | | method | |
| Example 8 | CuInSe₂ | 1.20 | 1.00 | 8 | 8 | 1.10 | Vacuum | KCN |
| | | | | | | | evaporation | etching |
| | | | | | | | method | |
| Example 9 | CuInSe₂ | 1.20 | 1.00 | 8 | 8 | 1.10 | Vacuum | KCN |
| | | | | | | | evaporation | etching |
| | | | | | | | method | |
| Example 10 | CuInSe₂ | 1.20 | 1.00 | 8 | 8 | 1.10 | Vacuum | KCN |
| | | | | | | | evaporation | etching |
| | | | | | | | method | |
| Example 11 | CuInSe₂ | 1.20 | 1.00 | 8 | 8 | 1.10 | Vacuum | KCN |
| | | | | | | | evaporation | etching |
| | | | | | | | method | |
| Example 12 | CuInSe₂ | 1.20 | 1.00 | 8 | 8 | 1.10 | Vacuum | KCN |
| | | | | | | | evaporation | etching |
| | | | | | | | method | |
| Example 13 | CuInSe₂ | 1.20 | 1.00 | 8 | 8 | 1.10 | Vacuum | KCN |
| | | | | | | | evaporation | etching |
| | | | | | | | method | |
| Example 14 | CuInSe₂ | 1.20 | 1.00 | 8 | 8 | 1.10 | Vacuum | KCN |
| | | | | | | | evaporation | etching |
| | | | | | | | method | |
| Comparative | CuInSe₂ | 1.20 | 1.00 | 8 | 8 | 1.10 | Vacuum | KCN |
| Example 4 | | | | | | | evaporation | etching |
| | | | | | | | method | |

TABLE 4

| | Second absorber layer | | | | |
|---|---|---|---|---|---|
| | | | Film | | |
| | | Ib group/IIIb group | thickness | | Film forming |
| | Material | composition ratio | (nm) | Production method | temperature (° C.) |
| Comparative | CuInSe₂ | 0.05 | 20 | Vacuum evaporation method In + Se | 200 |
| Example 3 | | | | | |
| Example 7 | CuInSe₂ | 0.10 | 20 | Vacuum evaporation method In + Se | 250 |
| Example 8 | CuInSe₂ | 0.35 | 20 | Vacuum evaporation method In + Se | 300 |
| Example 9 | CuInSe₂ | 0.50 | 20 | Vacuum evaporation method In + Se | 350 |
| Example 10 | CuInSe₂ | 0.60 | 20 | Vacuum evaporation method In + Se | 400 |
| Example 11 | CuInSe₂ | 0.90 | 20 | Vacuum evaporation method In + Se | 450 |
| Example 12 | CuInSe₂ | 0.35 | 20 | Vacuum evaporation method Cu + In + Se | 350 |
| Example 13 | CuInSe₂ | 0.50 | 20 | Vacuum evaporation method Cu + In + Se | 450 |
| Example 14 | CuInSe₂ | 0.65 | 20 | Vacuum evaporation method Cu + In + Se | 550 |
| Comparative | CuInSe₂ | 1.05 | 20 | Vacuum evaporation method Cu + In + Se | 550 |
| Example 4 | | | | | |

### Examples 15 to 21

As the first p-type absorber layer, the material shown in Table 5 was used.

At the first p-type absorber layer film forming step, the flux was set such that the Ib group/IIIb group composition ratio immediately after formation of the film might be a value shown in Table 5.

In the case where the first p-type absorber layer contained a plurality of IIIb group elements, the flux was set such that the composition thereof might be a value shown in Table 5.

After the substrate was heated to 540° C., the shutters of the elements as the first p-type absorber layer material shown in Table 5 each were opened to deposit the elements on the substrate.

Except the description above, solar cells of Example 15 to 21 were produced by the same method as that in Example 1.

The compound used for the first p-type absorber layer, the Ib group/IIIb group composition ratio in the first p-type absorber layer immediately after formation of the film, the Ib group/IIIb group composition ratio in the first p-type absorber layer after the secondary phase removing treatment, the half width value of the luminescence with the narrowest half width in the photoluminescence spectrum and the cathodoluminescence spectrum of the first p-type absorber layer, the value of k in the measurement of the excitation light intensity dependence of the intensity of photoluminescence, and the secondary phase removing method are shown in Table 5.

The compound used for the second absorber layer, the ratio of the Ib group/IIIb group composition contained in the second absorber layer obtained in the AES measurement, the film thickness of the second absorber layer, the method for producing the second absorber layer, and the film forming temperature are shown in Table 6.

### Comparative Examples 5 to 11

As the p-type absorber layer, the material shown in Table 5 was used.

The second absorber layer was not provided.

Except the description above, solar cells of Comparative Example 5 to 11 were produced by the same method as that in Examples 15 to 21.

The compound used for the p-type absorber layer, the Ib group/IIIb group composition ratio in the p-type absorber layer immediately after formation of the film, the Ib group/IIIb group composition ratio after the secondary phase removing treatment, the half width value of the luminescence with the narrowest half width in the photoluminescence spectrum and the cathodoluminescence spectrum of the p-type absorber layer, the value of k in the measurement of the excitation light intensity dependence of the intensity of photoluminescence, and the secondary phase removing method are shown in Table 5.

TABLE 5

| | First P-type absorber layer | | | | | | | |
|---|---|---|---|---|---|---|---|---|
| | | | Ib group/ | | | | | |
| | | | IIIb group | | | | | |
| | | | composition | | | | | |
| | | Ib group/ | ratio of | | | | | |
| | | IIIb group | first p-type | | | | | |
| | | composition | absorber | | | | | |
| | | ratio | layer (after | | | | | |
| | | immediately | secondary | | | | | Secondary |
| | | after | phase | Photo- | Cathodo- | Photo- | | phase |
| | | formation | removing | luminescence | luminescence | luminescence | Production | removing |
| Table 5 | Material | of film | treatment) | half width (meV) | half width (meV) | k value | method | treatment |
| Comparative | CuGaSe₂ | 1.23 | 1.00 | 13 | 13 | 1.10 | Vacuum | KCN |
| Example 5 | | | | | | | evaporation | etching |
| | | | | | | | method | |
| Comparative | Cu(In_{0.7}Ga_{0.3})Se₂ | 1.23 | 1.00 | 11 | 11 | 1.11 | Vacuum | KCN |
| Example 6 | | | | | | | evaporation | etching |
| | | | | | | | method | |
| Comparative | Cu(In_{0.5}Ga_{0.5})Se₂ | 1.23 | 1.00 | 12 | 12 | 1.16 | Vacuum | KCN |
| Example 7 | | | | | | | evaporation | etching |
| | | | | | | | method | |
| Comparative | Cu(In_{0.8}Al_{0.2})Se₂ | 1.23 | 1.00 | 14 | 14 | 1.19 | Vacuum | KCN |
| Example 8 | | | | | | | evaporation | etching |
| | | | | | | | method | |
| Comparative | CuInS₂ | 1.23 | 1.00 | 12 | 12 | 1.30 | Vacuum | KCN |
| Example 9 | | | | | | | evaporation | etching |
| | | | | | | | method | |
| Comparative | Cu(In_{0.7}Ga_{0.3})S | 1.23 | 1.00 | 13 | 13 | 1.35 | Vacuum | KCN |
| Example 10 | | | | | | | evaporation | etching |
| | | | | | | | method | |
| Comparative | AgInSe₂ | 1.23 | 1.00 | 14 | 14 | 1.40 | Vacuum | KCN |
| Example 11 | | | | | | | evaporation | etching |
| | | | | | | | method | |
| Example 15 | CuGaSe₂ | 1.23 | 1.00 | 13 | 13 | 1.10 | Vacuum | KCN |
| | | | | | | | evaporation | etching |
| | | | | | | | method | |
| Example 16 | Cu(In_{0.7}Ga_{0.3})Se₂ | 1.23 | 1.00 | 11 | 11 | 1.11 | Vacuum | KCN |
| | | | | | | | evaporation | etching |
| | | | | | | | method | |
| Example 17 | Cu(In_{0.5}Ga_{0.5})Se₂ | 1.23 | 1.00 | 12 | 12 | 1.16 | Vacuum | KCN |
| | | | | | | | evaporation | etching |
| | | | | | | | method | |
| Example 18 | Cu(In_{0.8}Al_{0.2})Se₂ | 1.23 | 1.00 | 14 | 14 | 1.19 | Vacuum | KCN |
| | | | | | | | evaporation | etching |
| | | | | | | | method | |
| Example 19 | CuInS₂ | 1.23 | 1.00 | 12 | 12 | 1.30 | Vacuum | KCN |
| | | | | | | | evaporation | etching |
| | | | | | | | method | |
| Example 20 | Cu(In_{0.7}Ga_{0.3})S | 1.23 | 1.00 | 13 | 13 | 1.35 | Vacuum | KCN |
| | | | | | | | evaporation | etching |
| | | | | | | | method | |
| Example 21 | AgInSe₂ | 1.23 | 1.00 | 14 | 14 | 1.40 | Vacuum | KCN |
| | | | | | | | evaporation | etching |
| | | | | | | | method | |

TABLE 6

| | Second absorber layer | | | | |
|---|---|---|---|---|---|
| | | Ib group/IIIb group | Film thickness | | Film forming temperature |
| | Material | composition ratio | (nm) | Production method | (° C.) |
| Comparative | None | | | | |
| Example 5 | | | | | |
| Comparative | None | | | | |
| Example 6 | | | | | |
| Comparative | None | | | | |
| Example 7 | | | | | |
| Comparative | None | | | | |
| Example 8 | | | | | |
| Comparative | None | | | | |
| Example 9 | | | | | |
| Comparative | None | | | | |
| Example 10 | | | | | |
| Comparative | None | | | | |
| Example 11 | | | | | |
| Example 15 | CuInSe₂ | 0.35 | 20 | Vacuum evaporation method In + Se | 300 |
| Example 16 | CuInSe₂ | 0.35 | 20 | Vacuum evaporation method In + Se | 300 |
| Example 17 | CuInSe₂ | 0.35 | 20 | Vacuum evaporation method In + Se | 300 |
| Example 18 | CuInSe₂ | 0.35 | 20 | Vacuum evaporation method In + Se | 300 |
| Example 19 | CuInSe₂ | 0.35 | 20 | Vacuum evaporation method In + Se | 300 |
| Example 20 | CuInSe₂ | 0.35 | 20 | Vacuum evaporation method In + Se | 300 |
| Example 21 | CuInSe₂ | 0.35 | 20 | Vacuum evaporation method In + Se | 300 |

### Example 22

As the first p-type absorber layer, the material shown in Table 7 was used.

At the first p-type absorber layer film forming step, the flux was set such that the Ib group/IIIb group composition ratio immediately after formation of the film might be a value shown in Table 7.

Except the description above, a solar cell of Example 22 was produced by the same method as that in Example 1.

The compound used for the first p-type absorber layer, the Ib group/IIIb group composition ratio in the first p-type absorber layer immediately after formation of the film, the Ib group/IIIb group composition ratio in the first p-type absorber layer after the secondary phase removing treatment, the half width value of the luminescence with the narrowest half width in the photoluminescence spectrum and the cathodoluminescence spectrum of the first p-type absorber layer, the value of k in the measurement of the excitation light intensity dependence of the intensity of photoluminescence, and the secondary phase removing method are shown in Table 7.

The compound used for the second absorber layer, the ratio of the Ib group/IIIb group composition contained in the second absorber layer obtained in the AES measurement, the film thickness of the second absorber layer, the method for producing the second absorber layer, and the film forming temperature are shown in Table 8.

### Example 23

As the first p-type absorber layer, the material shown in Table 7 was used.

At the first p-type absorber layer film forming step, the flux was set such that the Ib group/IIIb group composition ratio immediately after formation of the film might be a value shown in Table 7.

After the secondary phase removing treatment of the first p-type absorber layer, a second absorber layer was formed on the p-type absorber layer by the vacuum evaporation method.

The substrate was placed within the chamber of the PVD machine, and the inside of the chamber was evacuated. The ultimate pressure within the vacuum chamber was 1.0×10⁻⁸ torr.

Then, after the substrate was heated to 300° C. and the temperature was stabilized, the shutters of the respective K cells of Ga and Se were opened to deposit Ga and Se on the substrate. At a point of time when a layer with a thickness of approximately 20 nm was formed on the substrate by this deposition, the shutter of the K cell of Ga was closed.

At the step, the second absorber layer was formed by supply of the Ib group element diffused from the first p-type absorber layer to the film surface direction and the IIIb group element and VIb group element from the surface by the deposition step.

Then, after the substrate was cooled to 200° C., the shutter of the K cell of Se was closed to complete the film formation of the second absorber layer.

Except the description above, a solar cell of Example 23 was produced by the same method as that in Example 1.

The compound used for the first p-type absorber layer, the Ib group/IIIb group composition ratio in the first p-type absorber layer immediately after formation of the film, the Ib group/IIIb group composition ratio in the first p-type absorber layer after the secondary phase removing treatment, the half width value of the luminescence with the narrowest half width in the photoluminescence spectrum and the cathodoluminescence spectrum of the first p-type absorber layer, the value of k in the measurement of the excitation light intensity dependence of the intensity of photoluminescence, and the secondary phase removing method are shown in Table 7.

The compound used for the second absorber layer, the ratio of the Ib group/IIIb group composition contained in the second absorber layer obtained in the AES measurement, the film thickness of the second absorber layer, the method for producing the second absorber layer, and the film forming temperature are shown in Table 8.

### Example 24

As the first p-type absorber layer, the material shown in Table 7 was used.

After the secondary phase removing treatment of the first p-type absorber layer, a second absorber layer was formed on the p-type absorber layer by the vacuum evaporation method.

After the secondary phase removing treatment of the first p-type absorber layer, the substrate was placed within the chamber of the PVD machine, and the inside of the chamber was evacuated. The ultimate pressure within the vacuum chamber was 1.0×10⁻⁸ torr.

Then, after the substrate was heated to 300° C. and the temperature was stabilized, the shutters of the respective K cells of Cu, In, and Se were opened to deposit Cu, In, and Se on the substrate. At a point of time when a layer with a thickness of approximately 20 nm was formed on the substrate by this deposition, the shutters of the K cells of Cu and In were closed.

At the step, the second absorber layer was formed by supply of the Ib group element diffused from the first p-type absorber layer to the film surface direction and the IIIb group element and VIb group element from the surface by the deposition step.

Then, after the substrate was cooled to 200° C., the shutter of the K cell of Se was closed to complete the film formation of the second absorber layer.

Except the description above, a solar cell of Example 24 was produced by the same method as that in Example 15.

The compound used for the first p-type absorber layer, the Ib group/IIIb group composition ratio in the first p-type absorber layer immediately after formation of the film, the Ib group/IIIb group composition ratio in the first p-type absorber layer after the secondary phase removing treatment, the half width value of the luminescence with the narrowest half width in the photoluminescence spectrum and the cathodoluminescence spectrum of the first p-type absorber layer, the value of k in the measurement of the excitation light intensity dependence of the intensity of photoluminescence, and the secondary phase removing method are shown in Table 7.

The compound used for the second absorber layer, the ratio of the Ib group/IIIb group composition contained in the second absorber layer obtained in the AES measurement, the film thickness of the second absorber layer, the method for producing the second absorber layer, and the film forming temperature are shown in Table 8.

### Example 25

As the first p-type absorber layer, the material shown in Table 7 was used.

Except the description above, a solar cell of Example 25 was produced by the same method as that in Example 15.

The compound used for the first p-type absorber layer, the Ib group/IIIb group composition ratio in the first p-type absorber layer immediately after formation of the film, the Ib group/IIIb group composition ratio after the secondary phase removing treatment, the half width value of the luminescence with the narrowest half width in the photoluminescence spectrum and the cathodoluminescence spectrum of the p-type absorber layer, the value of k in the measurement of the excitation light intensity dependence of the intensity of photoluminescence, and the secondary phase removing method are shown in Table 7.

The compound used for the second absorber layer, the ratio of the Ib group/IIIb group composition contained in the second absorber layer obtained in the AES measurement, the film thickness of the second absorber layer, the method for producing the second absorber layer, and the film forming temperature are shown in Table 8.

### Example 26

As the first p-type absorber layer, the material shown in Table 7 was used. Flux of each element was set such that the composition shown in Table 7 might be obtained. At the first p-type absorber layer film forming step, the flux was set such that the Ib group/IIIb group composition ratio immediately after formation of the film might be a value shown in Table 7.

After the secondary phase removing treatment of the first p-type absorber layer, a second absorber layer was formed on the p-type absorber layer by the vacuum evaporation method.

After the secondary phase removing treatment of the first p-type absorber layer, the substrate was placed within the chamber of the PVD machine, and the inside of the chamber was evacuated. The ultimate pressure within the vacuum chamber was 1.0×10⁻⁸ torr.

The temperatures of the respective K cells were set such that the ratio of the flux of In to that of Ga might be the same at the first p-type absorber layer film forming step. Then, after the substrate was heated to the temperature shown in Table 8 and the temperature was stabilized, the shutters of the respective K cells of In, Ga, Se were opened to deposit In, Ga, and Se on the substrate. At a point of time when a layer with a thickness of approximately 20 nm was formed on the substrate by this deposition, the shutters of the K cells of In and Ga were closed. Then, after the substrate was cooled to 200° C., the shutter of the K cell of Se was closed to complete the film formation of the second absorber layer.

Except the description above, a solar cell of Example 26 was produced by the same method as that in Example 15.

The compound used for the first p-type absorber layer, the Ib group/IIIb group composition ratio in the first p-type absorber layer immediately after formation of the film, the Ib group/IIIb group composition ratio in the first p-type absorber layer after the secondary phase removing treatment, the half width value of the luminescence with the narrowest half width in the photoluminescence spectrum and the cathodoluminescence spectrum of the first p-type absorber layer, the value of k in the measurement of the excitation light intensity dependence of the intensity of photoluminescence, and the secondary phase removing method are shown in Table 7.

The compound used for the second absorber layer, the ratio of the Ib group/IIIb group composition contained in the second absorber layer obtained in the AES measurement, the film thickness of the second absorber layer, the method for producing the second absorber layer, and the film forming temperature are shown in Table 8.

### Example 27

The ratio of the flux of In to that of Ga at the second absorber layer forming step was set such that the composition ratio Ga/(In+Ga) in the second absorber layer might be 0.3.

Except the description above, a solar cell of Example 27 was produced by the same method as that in Example 26.

The compound used for the first p-type absorber layer, the Ib group/IIIb group composition ratio in the first p-type absorber layer immediately after formation of the film, the Ib group/IIIb group composition ratio in the first p-type absorber layer after the secondary phase removing treatment, the half width value of the luminescence with the narrowest half width in the photoluminescence spectrum and the cathodoluminescence spectrum of the first p-type absorber layer, the value of k in the measurement of the excitation light intensity dependence of the intensity of photoluminescence, and the secondary phase removing method are shown in Table 7.

The compound used for the second absorber layer, the ratio of the Ib group/IIIb group composition contained in the second absorber layer obtained in the AES measurement, the film thickness of the second absorber layer, the method for producing the second absorber layer, and the film forming temperature are shown in Table 8.

TABLE 7

| | First p-type absorber layer | | | | | | | |
|---|---|---|---|---|---|---|---|---|
| | | | Ib group/ | | | | | |
| | | | IIIb group | | | | | |
| | | | composition | | | | | |
| | | Ib group/ | ratio of | | | | | |
| | | IIIb group | first p-type | | | | | |
| | | composition | absorber | | | | | |
| | | ratio | layer (after | | | | | |
| | | immediately | secondary | | | | | Secondary |
| | | after | phase | Photo- | Cathodo- | Photo- | | phase |
| | | formation | removing | luminescence | luminescence | luminescence | Production | removing |
| Table 7 | Material | of film | treatment) | half width (meV) | half width (meV) | k value | method | treatment |
| Example 22 | CuInSe₂ | 1.24 | 1.00 | 7 | 7 | 1.21 | Vacuum | KCN |
| | | | | | | | evaporation | etching |
| | | | | | | | method | |
| Example 23 | CuInSe₂ | 1.24 | 1.00 | 7 | 7 | 1.21 | Vacuum | KCN |
| | | | | | | | evaporation | etching |
| | | | | | | | method | |
| Example 24 | AgInSe₂ | 1.24 | 1.00 | 13 | 13 | 1.42 | Vacuum | KCN |
| | | | | | | | evaporation | etching |
| | | | | | | | method | |
| Example 25 | AgInSe₂ | 1.24 | 1.00 | 13 | 13 | 1.42 | Vacuum | KCN |
| | | | | | | | evaporation | etching |
| | | | | | | | method | |
| Example 26 | Cu(In_{0.5}Ga_{0.5})Se₂ | 1.24 | 1.00 | 8 | 8 | 1.15 | Vacuum | KCN |
| | | | | | | | evaporation | etching |
| | | | | | | | method | |
| Example 27 | Cu(In_{0.5}Ga_{0.5})Se₂ | 1.24 | 1.00 | 8 | 8 | 1.15 | Vacuum | KCN |
| | | | | | | | evaporation | etching |
| | | | | | | | method | |

TABLE 8

| | Second absorber layer | | | | |
|---|---|---|---|---|---|
| | | Ib group/IIIb | | | |
| | | group | Film | | Film forming |
| | | composition | thickness | Production | temperature |
| | Material | ratio | (nm) | method | (° C.) |
| Example | CuInSe₂ | 0.35 | 20 | Vacuum | 300 |
| 22 | | | | evaporation | |
| | | | | method In + Se | |
| Example | CuGaSe₂ | 0.35 | 20 | Vacuum | 300 |
| 23 | | | | evaporation | |
| | | | | method Ga + Se | |
| Example | (Ag_{0.3}Cu_{0.7})InSe₂ | 0.35 | 20 | Vacuum | 300 |
| 24 | | | | evaporation | |
| | | | | method | |
| | | | | Cu + In + Se | |
| Example | AgInSe₂ | 0.35 | 20 | Vacuum | 300 |
| 25 | | | | evaporation | |
| | | | | method In + Se | |
| Example | Cu(In_{0.5}Ga_{0.5})Se₂ | 0.35 | 20 | Vacuum | 300 |
| 26 | | | | evaporation | |
| | | | | method | |
| | | | | In + Ga + Se | |
| Example | Cu(In_{0.7}Ga_{0.3})Se₂ | 0.35 | 20 | Vacuum | 300 |
| 27 | | | | evaporation | |
| | | | | method | |
| | | | | In + Ga + Se | |

### Examples 28 and 29

As the first p-type absorber layer, the material shown in Table 9 was used. At the first p-type absorber layer film forming step, the flux was set such that the Ib group/IIIb group composition ratio immediately after formation of the film might be a value shown in Table 9. The flux was set such that the ratio of a plurality of IIIb group elements might be a value shown in Table 9.

Except the description above, solar cells of Examples 28 and 29 were produced by the same method as that in Example 26.

The compound used for the first p-type absorber layer, the Ib group/IIIb group composition ratio in the first p-type absorber layer immediately after formation of the film, the Ib group/IIIb group composition ratio after the secondary phase removing treatment, the half width value of the luminescence with the narrowest half width in the photoluminescence spectrum and the cathodoluminescence spectrum of the first p-type absorber layer, the value of k in the measurement of the excitation light intensity dependence of the intensity of photoluminescence, and the secondary phase removing method are shown in Table 9.

The compound used for the second absorber layer, the ratio of the Ib group/IIIb group composition contained in the second absorber layer obtained in the AES measurement, the film thickness of the second absorber layer, the method for producing the second absorber layer, and the film forming temperature are shown in Table 10.

TABLE 9

| | First p-type absorber layer | | | | | | | |
|---|---|---|---|---|---|---|---|---|
| | | | Ib group/ | | | | | |
| | | | IIIb group | | | | | |
| | | | composition | | | | | |
| | | Ib group/ | ratio of | | | | | |
| | | IIIb group | first p-type | | | | | |
| | | composition | absorber | | | | | |
| | | ratio | layer (after | | | | | |
| | | immediately | secondary | | | | | Secondary |
| | | after | phase | Photo- | Cathodo- | Photo- | | phase |
| | | formation | removing | luminescence | luminescence | luminescence | Production | removing |
| Table 9 | Material | of film | treatment) | half width (meV) | half width (meV) | k value | method | treatment |
| Example 28 | Cu(In_{0.5}Ga_{0.5})Se₂ | 1.20 | 1.00 | 8 | 8 | 1.10 | Vacuum | KCN |
| | | | | | | | evaporation | etching |
| | | | | | | | method | |
| Example 29 | Ag(In_{0.5}Ga_{0.5})Se₂ | 1.20 | 1.00 | 14 | 14 | 1.25 | Vacuum | KCN |
| | | | | | | | evaporation | etching |
| | | | | | | | method | |

TABLE 10

| | Second absorber layer | | | | |
|---|---|---|---|---|---|
| | | Ib group/IIIb | | | |
| | | group | Film | | Film forming |
| | | composition | thickness | Production | temperature |
| | Material | ratio | (nm) | method | (° C.) |
| Example | Cu(In_{0.5}Ga_{0.5})Se₂ | 0.35 | 20 | Vacuum | 300 |
| 28 | | | | evaporation | |
| | | | | method In + Ga + Se | |
| Example | Ag(In_{0.5}Ga_{0.5})Se₂ | 0.35 | 20 | Vacuum | 300 |
| 29 | | | | evaporation | |
| | | | | method In + Ga + Se | |

### Examples 30 to 36

As the first p-type absorber layer, the material showing in Table 11 was used. At the first p-type absorber layer film forming step, the flux was set such that the Ib group/IIIb group composition ratio immediately after formation of the film might be a value shown in Table 11.

After the secondary phase removing treatment of the first p-type absorber layer, a second absorber layer was formed on the first p-type absorber layer by the vacuum evaporation method.

The substrate was placed within the chamber of the PVD machine, and the inside of the chamber was evacuated. The ultimate pressure within the vacuum chamber was 1.0×10⁻⁸ torr.

The temperatures of the respective K cells were set such that the ratio of the flux of In to that of Ga might be the same as that in the first p-type absorber layer film forming step. Then, after the substrate was heated to the temperature shown in Table 12 and the temperature was stabilized, the shutters of the respective K cells of In, Ga, Se were opened to deposit In, Ga and Se on the substrate. At a point of time when a layer with a thickness shown in Table 12 was formed on the substrate by this deposition, the shutters of the K cells of In and Ga were closed.

Then, after the substrate was cooled to 200° C., the shutter of the K cell of Se was closed to complete the film formation of the second absorber layer.

Except the description above, solar cells of Examples 30 to 36 were produced by the same method as that in Example 26.

The compound used for the first p-type absorber layer, the Ib group/IIIb group composition ratio in the first p-type absorber layer immediately after formation of the film, the Ib group/IIIb group composition ratio after the secondary phase removing treatment, the half width value of the luminescence with the narrowest half width in the photoluminescence spectrum and the cathodoluminescence spectrum of the first p-type absorber layer, the value of k in the measurement of the excitation light intensity dependence of the intensity of photoluminescence, and the secondary phase removing method are shown in Table 11.

The compound used for the second absorber layer, the ratio of the Ib group/IIIb group composition contained in the second absorber layer obtained in the AES measurement, the film thickness of the second absorber layer, the method for producing the second absorber layer, and the film forming temperature are shown in Table 12.

TABLE 11

| | First p-type absorber layer | | | | | | | |
|---|---|---|---|---|---|---|---|---|
| | | | Ib group/ | | | | | |
| | | | IIIb group | | | | | |
| | | | composition | | | | | |
| | | Ib group/ | ratio of | | | | | |
| | | IIIb group | first p-type | | | | | |
| | | composition | absorber | | | | | |
| | | ratio | layer (after | | | | | |
| | | immediately | secondary | | | | | Secondary |
| | | after | phase | Photo- | Cathodo- | Photo- | | phase |
| | | formation | removing | luminescence | luminescence | luminescence | Production | removing |
| Table 11 | Material | of film | treatment) | half width (meV) | half width (meV) | k value | method | treatment |
| Example 30 | Cu(In_{0.5}Ga_{0.5})Se₂ | 1.20 | 1.00 | 8 | 8 | 1.10 | Vacuum | KCN |
| | | | | | | | evaporation | etching |
| | | | | | | | method | |
| Example 31 | Cu(In_{0.5}Ga_{0.5})Se₂ | 1.20 | 1.00 | 8 | 8 | 1.10 | Vacuum | KCN |
| | | | | | | | evaporation | etching |
| | | | | | | | method | |
| Example 32 | Cu(In_{0.5}Ga_{0.5})Se₂ | 1.20 | 1.00 | 8 | 8 | 1.10 | Vacuum | KCN |
| | | | | | | | evaporation | etching |
| | | | | | | | method | |
| Example 33 | Cu(In_{0.5}Ga_{0.5})Se₂ | 1.20 | 1.00 | 8 | 8 | 1.10 | Vacuum | KCN |
| | | | | | | | evaporation | etching |
| | | | | | | | method | |
| Example 34 | Cu(In_{0.5}Ga_{0.5})Se₂ | 1.20 | 1.00 | 8 | 8 | 1.10 | Vacuum | KCN |
| | | | | | | | evaporation | etching |
| | | | | | | | method | |
| Example 35 | Cu(In_{0.5}Ga_{0.5})Se₂ | 1.20 | 1.00 | 8 | 8 | 1.10 | Vacuum | KCN |
| | | | | | | | evaporation | etching |
| | | | | | | | method | |
| Example 36 | Cu(In_{0.5}Ga_{0.5})Se₂ | 1.20 | 1.00 | 8 | 8 | 1.10 | Vacuum | KCN |
| | | | | | | | evaporation | etching |
| | | | | | | | method | |

TABLE 12

| | Second absorber layer | | | | |
|---|---|---|---|---|---|
| | | Ib group/IIIb | | | |
| | | group | Film | | Film forming |
| | | composition | thickness | Production | temperature |
| | Material | ratio | (nm) | method | (° C.) |
| Example | Cu(In_{0.5}Ga_{0.5})Se₂ | 0.35 | 0.5 | Vacuum | 300 |
| 30 | | | | evaporation | |
| | | | | method In + Ga + Se | |
| Example | Cu(In_{0.5}Ga_{0.5})Se₂ | 0.35 | 1.1 | Vacuum | 300 |
| 31 | | | | evaporation | |
| | | | | method In + Ga + Se | |
| Example | Cu(In_{0.5}Ga_{0.5})Se₂ | 0.35 | 12 | Vacuum | 300 |
| 32 | | | | evaporation | |
| | | | | method In + Ga + Se | |
| Example | Cu(In_{0.5}Ga_{0.5})Se₂ | 0.35 | 30 | Vacuum | 300 |
| 33 | | | | evaporation | |
| | | | | method In + Ga + Se | |
| Example | Cu(In_{0.5}Ga_{0.5})Se₂ | 0.35 | 45 | Vacuum | 300 |
| 34 | | | | evaporation | |
| | | | | method In + Ga + Se | |
| Example | Cu(In_{0.5}Ga_{0.5})Se₂ | 0.35 | 70 | Vacuum | 300 |
| 35 | | | | evaporation | |
| | | | | method In + Ga + Se | |
| Example | Cu(In_{0.5}Ga_{0.5})Se₂ | 0.35 | 110 | Vacuum | 300 |
| 36 | | | | evaporation | |
| | | | | method In + Ga + Se | |

### Example 37

As the first p-type absorber layer, the material shown in Table 13 was used. At the first p-type absorber layer film forming step, the flux was set such that the Ib group/IIIb group composition ratio immediately after formation of the film might be a value shown in Table 13.

After formation of the first p-type absorber layer, the secondary phase removing treatment was not performed, and a second absorber layer was formed on the first p-type absorber layer.

Except the description above, a solar cell of Example 37 was produced by the same method as that in Example 26.

The compound used for the first p-type absorber layer, the Ib group/IIIb group composition ratio in the first p-type absorber layer immediately after formation of the film, the half width value of the luminescence with the narrowest half width in the photoluminescence spectrum and the cathodoluminescence spectrum of the first p-type absorber layer, the value of k in the measurement of the excitation light intensity dependence of the intensity of photoluminescence, and the secondary phase removing method are shown in Table 13.

The compound used for the second absorber layer, the ratio of the Ib group/IIIb group composition contained in the second absorber layer obtained in the AES measurement, the film thickness of the second absorber layer, the method for producing the second absorber layer, and the film forming temperature are shown in Table 14.

### Example 38

As the first p-type absorber layer, the material shown in Table 13 was used. At the first p-type absorber layer film forming step, the flux was set such that the Ib group/IIIb group composition ratio immediately after formation of the film might be a value shown in Table 13.

Except the description above, a solar cell of Example 38 was produced by the same method as that in Example 26.

The compound used for the first p-type absorber layer, the Ib group/IIIb group composition ratio in the first p-type absorber layer immediately after formation of the film, the Ib group/IIIb group composition ratio after the secondary phase removing treatment, the half width value of the luminescence with the narrowest half width in the photoluminescence spectrum and the cathodoluminescence spectrum of the first p-type absorber layer, the value of k in the measurement of the excitation light intensity dependence of the intensity of photoluminescence, and the secondary phase removing method are shown in Table 13.

The compound used for the second absorber layer, the ratio of the Ib group/IIIb group composition contained in the second absorber layer obtained in the AES measurement, the film thickness of the second absorber layer, the method for producing the second absorber layer, and the film forming temperature are shown in Table 14.

### Example 39

As the first p-type absorber layer, the material shown in Table 13 was used. At the first p-type absorber layer film forming step, the flux was set such that the Ib group/IIIb group composition ratio immediately after formation of the film might be a value shown in Table 13.

After film formation of the first p-type absorber layer, the substrate was placed within a rapid heating heat treatment furnace. The heat treatment was performed while a foaming gas (H₂ 95%, N₂ 5%) was supplied into the furnace at a flow rate of 200 sccm. The temperature was 400° C., the temperature raising rate was 400° C./min, and the heat treatment time was 30 s. After the heat treatment, cooling to 50° C. was performed at a rate of 50° C./min, and the substrate was taken out. By this treatment, removal of a secondary phase Ib group-VIb group compound contained in the first p-type absorber layer was performed.

Except the description above, a solar cell of Example 39 was produced by the same method as that in Example 26.

The compound used for the first p-type absorber layer, the Ib group/IIIb group composition ratio in the first p-type absorber layer immediately after formation of the film, the Ib group/IIIb group composition ratio after the secondary phase removing treatment, the half width value of the luminescence with the narrowest half width in the photoluminescence spectrum and the cathodoluminescence spectrum of the first p-type absorber layer, the value of k in the measurement of the excitation light intensity dependence of the intensity of photoluminescence, and the secondary phase removing method are shown in Table 13.

The compound used for the second absorber layer, the ratio of the Ib group/IIIb group composition contained in the second absorber layer obtained in the AES measurement, the film thickness of the second absorber layer, the method for producing the second absorber layer, and the film forming temperature are shown in Table 14.

### Example 40

As the first p-type absorber layer, the material shown in Table 13 was used. At the first p-type absorber layer film forming step, the flux was set such that the Ib group/IIIb group composition ratio immediately after formation of the film might be a value shown in Table 13.

After film formation of the first p-type absorber layer, the substrate was placed within an electrolyzer provided with a 3-electrode cell. A Pt plate was a counter electrode, a saturated calomel electrode was a reference electrode, and an Mo back electrode exposed on the substrate was a working electrode. The electrolyzer was filled with a 0.1M H₂SO₄ solution (pH=1.2), and a potential was changed from −0.5 V to +0.5 V at a scan rate of 10 mV/s to perform electrochemical etching. By this treatment, removal of a secondary phase Ib group-VIb group compound contained in the first p-type absorber layer was performed.

Except the description above, a solar cell of Example 40 was produced by the same method as that in Example 26.

The compound used for the first p-type absorber layer, the Ib group/IIIb group composition ratio in the first p-type absorber layer immediately after formation of the film, the Ib group/IIIb group composition ratio after the secondary phase removing treatment, the half width value of the luminescence with the narrowest half width in the photoluminescence spectrum and the cathodoluminescence spectrum of the p-type absorber layer, the value of k in the measurement of the excitation light intensity dependence of the intensity of photoluminescence, and the secondary phase removing method are shown in Table 13.

The compound used for the second absorber layer, the ratio of the Ib group/IIIb group composition contained in the second absorber layer obtained in the AES measurement, the film thickness of the second absorber layer, the method for producing the second absorber layer, and the film forming temperature are shown in Table 14.

### Example 41

As the first p-type absorber layer, the material shown in Table 13 was used. At the first p-type absorber layer film forming step, the flux was set such that the Ib group/IIIb group composition ratio immediately after formation of the film might be a value shown in Table 13.

After film formation of the first p-type absorber layer, while the substrate was left within the vacuum chamber of the same PVD machine as it was, the temperature of the substrate was reduced to 300° C. The temperatures of the respective K cells was set such that the ratio of the flux of In to that of Ga might be the same as that in the first p-type absorber layer film forming step. Then, the shutters of the respective K cells of In, Ga, and Se were opened to deposit In, Ga, and Se on the substrate. By this deposition, the secondary phase CuxSe phase existing in the first p-type absorber layer was reacted with In and Ga to remove the secondary phase. At a point of time when no secondary phase exists, the shutters of the K cells of In and Ga were closed. Monitoring of presence of the secondary phase was performed by surface roughness measurement by laser light.

After the secondary phase removing step, subsequently, film formation of the second absorber layer was performed in the PVD machine.

Except the description above, a solar cell of Example 41 was produced by the same method as that in Example 26.

The compound used for the first p-type absorber layer, the Ib group/IIIb group composition ratio in the first p-type absorber layer immediately after formation of the film, the Ib group/IIIb group composition ratio after the secondary phase removing treatment, the half width value of the luminescence with the narrowest half width in the photoluminescence spectrum and the cathodoluminescence spectrum of the p-type absorber layer, the value of k in the measurement of the excitation light intensity dependence of the intensity of photoluminescence, and the secondary phase removing method are shown in Table 13.

The compound used for the second absorber layer, the ratio of the Ib group/IIIb group composition contained in the second absorber layer obtained in the AES measurement, the film thickness of the second absorber layer, the method for producing the second absorber layer, and the film forming temperature are shown in Table 14.

TABLE 13

| | First p-type absorber layer | | | | | | | |
|---|---|---|---|---|---|---|---|---|
| | | Ib group/ | | | | | | |
| | | IIIb group | Ib group/ | | | | | |
| | | composition | IIIb group | | | | | |
| | | ratio | composition | | | | | |
| | | immediately | ratio of | | | | | Secondary |
| | | after | first p-type | Photo- | Cathodo- | Photo- | | phase |
| | | formation | absorber | luminesccnce | luminescence | luminescence | Production | removing |
| Table 13 | Material | of film | layer | half width (meV) | half width (meV) | k value | method | treatment |
| Example 37 | Cu(In_{0.5}Ga_{0.5})Se₂ | 1.00 | 1.00 | 13 | 13 | 1.01 | Vacuum | None |
| | | | | | | | evaporation | |
| | | | | | | | method | |
| Example 38 | Cu(In_{0.5}Ga_{0.5})Se₂ | 1.10 | 1.00 | 9 | 9 | 1.02 | Vacuum | KCN |
| | | | | | | | evaporation | etching |
| | | | | | | | method | |
| Example 39 | Cu(In_{0.5}Ga_{0.5})Se₂ | 1.10 | 1.00 | 9 | 9 | 1.02 | Vacuum | Foaming gas |
| | | | | | | | evaporation | atmosphere heat |
| | | | | | | | method | treatment |
| Example 40 | Cu(In_{0.5}Ga_{0.5})Se₂ | 1.10 | 1.00 | 9 | 9 | 1.02 | Vacuum | Electrochemical |
| | | | | | | | evaporation | etching |
| | | | | | | | method | |
| Example 41 | Cu(In_{0.5}Ga_{0.5})Se₂ | 1.10 | 1.00 | 9 | 9 | 1.02 | Vacuum | IIIb group-VIb |
| | | | | | | | evaporation | group elements |
| | | | | | | | method | deposition |

TABLE 14

| | Second absorber layer | | | | |
|---|---|---|---|---|---|
| | | Ib group/IIIb | | | |
| | | group | Film | | Film forming |
| | | composition | thickness | Production | temperature |
| | Material | ratio | (nm) | method | (° C.) |
| Example | Cu(In_{0.5}Ga_{0.5})Se₂ | 0.35 | 20 | Vacuum | 300 |
| 37 | | | | evaporation | |
| | | | | method In + Ga + Se | |
| Example | Cu(In_{0.5}Ga_{0.5})Se₂ | 0.35 | 20 | Vacuum | 300 |
| 38 | | | | evaporation | |
| | | | | method In + Ga + Se | |
| Example | Cu(In_{0.5}Ga_{0.5})Se₂ | 0.35 | 20 | Vacuum | 300 |
| 39 | | | | evaporation | |
| | | | | method In + Ga + Se | |
| Example | Cu(In_{0.5}Ga_{0.5})Se₂ | 0.35 | 20 | Vacuum | 300 |
| 40 | | | | evaporation | |
| | | | | method In + Ga + Se | |
| Example | Cu(In_{0.5}Ga_{0.5})Se₂ | 0.35 | 20 | Vacuum | 300 |
| 41 | | | | evaporation | |
| | | | | method In + Ga + Se | |

### Example 42

As the first p-type absorber layer, the material shown in Table 15 was used. At the first p-type absorber layer film forming step, the flux was set such that the Ib group/IIIb group composition ratio immediately after formation of the film might be a value shown in Table 15.

Except the description above, a solar cell of Example 42 was produced by the same method as that in Example 26.

The compound used for the first p-type absorber layer, the Ib group/IIIb group composition ratio in the first p-type absorber layer immediately after formation of the film, the III group/IIIb group composition ratio in the first p-type absorber layer after the secondary phase removing treatment, the half width value of the luminescence with the narrowest half width in the photoluminescence spectrum and the cathodoluminescence spectrum of the first p-type absorber layer, the value of k in the measurement of the excitation light intensity dependence of the intensity of photoluminescence, and the secondary phase removing method are shown in Table 15.

The compound used for the second absorber layer, the ratio of the Ib group/IIIb group composition contained in the second absorber layer obtained in the AES measurement, the film thickness of the second absorber layer, the method for producing the second absorber layer, and the film forming temperature are shown in Table 16.

### Example 43

As the first p-type absorber layer, the material shown in Table 15 was used. At the first p-type absorber layer film forming step, the flux was set such that the Ib group/IIIb group composition ratio immediately after formation of the film might be a value shown in Table 15.

After formation of the first p-type absorber layer, the substrate was immersed in a potassium cyanide aqueous solution (10 wt %) for 5 minutes, and removal of a secondary phase Ib group-VIb group compound contained in the first p-type absorber layer was performed.

Then, the substrate on which the first p-type absorber layer was formed was placed in a sputtering apparatus to perform formation of a second absorber layer by the sputtering method.

Hereinafter, details of formation of the second absorber layer by the sputtering method will be described.

The substrate was placed within the sputtering apparatus, and the inside of the apparatus was evacuated. The ultimate pressure was 1.0×10⁻⁶ torr. After evacuation, the substrate was heated to 300° C. Then, while gaseous Ar was continuously supplied into the chamber, a target composed of (In_{0.5}Ga_{0.5})₂Se₃ was sputtered within the chamber to form a film on the substrate placed facing the target. During formation of the film, the flow rate of gaseous Ar was set such that the pressure within the chamber might be 1 Pa. The second absorber layer was formed by supply of the Ib group element diffused from the p-type absorber layer to the film surface direction and (In_{0.5}Ga_{0.5})₂Se₃ by the sputtering step. When the thickness of the second absorber layer reached 20 nm, sputtering was terminated. By this step, the second absorber layer was formed.

Except the description above, a solar cell of Example 43 was produced by the same method as that in Example 26.

The compound used for the first p-type absorber layer, the Ib group/IIIb group composition ratio in the first p-type absorber layer immediately after formation of the film, the Ib group/IIIb group composition ratio after the secondary phase removing treatment, the half width value of the luminescence with the narrowest half width in the photoluminescence spectrum and the cathodoluminescence spectrum of the first p-type absorber layer, the value of k in the measurement of the excitation light intensity dependence of the intensity of photoluminescence, and the secondary phase removing method are shown in Table 15.

The compound used for the second absorber layer, the ratio of the Ib group/IIIb group composition contained in the second absorber layer obtained in the AES measurement, the film thickness of the second absorber layer, the method for producing the second absorber layer, and the film forming temperature are shown in Table 16.

### Comparative Example 12

A first p-type absorber layer was formed by the sputtering method and the heat treatment subsequent thereto. Hereinafter, details will be shown.

A substrate on which a back electrode was formed was placed within a sputtering apparatus, formation of a precursor layer was performed by the sputtering method. Then, the substrate was placed within an annealing furnace, and a heat treatment was performed for formation of the first p-type semiconductor layer. Hereinafter, details of formation of the first p-type semiconductor layer by the sputtering method and the heat treatment subsequent thereto will be described.

At the sputtering step, while gaseous Ar was continuously supplied into the chamber, a target composed of a Cu—Ga alloy (Cu 50%, Ga 50 at %) was sputtered within the chamber; then, a target composed of metallic In was sputtered. By this sputtering step, a precursor layer in which a Cu—Ga alloy layer and an In layer were sequentially laminated was obtained. At the sputtering step, the thickness of the Cu—Ga layer was 670 nm, and that of the In layer was 330 nm. Moreover, at the sputtering step, the temperature of the substrate was 200° C., and the flow rate of gaseous Ar was set such that the pressure within the chamber might be 1 Pa.

At the heat treatment step after the sputtering step, the precursor layer was heated in an H₂Se atmosphere at 550° C. for 1 hour to perform selenization of the precursor layer; thus, a first p-type semiconductor layer with a thickness of 2 μm was formed.

After the secondary phase removing treatment, the second absorber layer was not provided.

Except the description above, a solar cell of Comparative Example 12 was produced by the same method as that in Example 26.

The compound used for the p-type absorber layer, the Ib group/IIIb group composition ratio in the p-type absorber layer immediately after formation of the film, the Ib group/IIIb group composition ratio after the secondary phase removing treatment, the half width value of the luminescence with the narrowest half width in the photoluminescence spectrum and the cathodoluminescence spectrum of the p-type absorber layer, the value of k in the measurement of the excitation light intensity dependence of the intensity of photoluminescence, and the secondary phase removing method are shown in Table 15.

### Example 44

A first p-type absorber layer was formed by the sputtering method and the heat treatment subsequent thereto in the same manner as in Comparative Example 12.

A second absorber layer was formed by the sputtering method in the same manner as in Example 43.

Except the description above, a solar cell of Example 44 was produced by the same method as that in Example 26.

The compound used for the first p-type absorber layer, the Ib group/IIIb group composition ratio in the first p-type absorber layer immediately after formation of the film, the Ib group/IIIb group composition ratio after the secondary phase removing treatment, the half width value of the luminescence with the narrowest half width in the photoluminescence spectrum and the cathodoluminescence spectrum of the first p-type absorber layer, the value of k in the measurement of the excitation light intensity dependence of the intensity of photoluminescence, and the secondary phase removing method are shown in Table 15.

The compound used for the second absorber layer, the ratio of the Ib group/IIIb group composition contained in the second absorber layer obtained in the AES measurement, the film thickness of the second absorber layer, the method for producing the second absorber layer, and the film forming temperature are shown in Table 16.

TABLE 15

| | First p-type absorber layer | | | | | | | |
|---|---|---|---|---|---|---|---|---|
| | | | Ib group/ | | | | | |
| | | | IIIb group | | | | | |
| | | | composition | | | | | |
| | | Ib group/ | ratio of | | | | | |
| | | IIIb group | first p-type | | | | | |
| | | composition | absorber | | | | | |
| | | ratio | layer (after | | | | | |
| | | immediately | secondary | | | | | Secondary |
| | | after | phase | Photo- | Cathodo- | Photo- | | phase |
| | | formation | removing | luminescence | luminescence | luminescence | Production | removing |
| Table 15 | Material | of film | treatment) | half width (meV) | half width (meV) | k value | method | treatment |
| Example 42 | Cu(In_{0.5}Ga_{0.5})Se₂ | 1.26 | 1.00 | 8 | 8 | 1.16 | Vacuum | KCN |
| | | | | | | | evaporation | etching |
| | | | | | | | method | |
| Example 43 | Cu(In_{0.5}Ga_{0.5})Se₂ | 1.26 | 1.00 | 8 | 8 | 1.16 | Vacuum | KCN |
| | | | | | | | evaporation | etching |
| | | | | | | | method | |
| Comparative | Cu(In_{0.5}Ga_{0.5})Se₂ | 1.26 | 1.00 | 12 | 12 | 1.05 | Sputtering | KCN |
| Example 12 | | | | | | | method | etching |
| Example 44 | Cu(In_{0.5}Ga_{0.5})Se₂ | 1.26 | 1.00 | 12 | 12 | 1.05 | Sputtering | KCN |
| | | | | | | | method | etching |

TABLE 16

Second absorber layer

| | | Ib group/IIIb | | | |
|---|---|---|---|---|---|
| | | group | Film | | Film forming |
| | | composition | thickness | Production | temperature |
| | Material | ratio | (nm) | method | (° C.) |
| Example 42 | Cu(In_{0.5}Ga_{0.5})Se₂ | 0.35 | 20 | Vacuum | 300 |
| | | | | evaporation | |
| | | | | method | |
| | | | | In + Ga + Se | |
| Example 43 | Cu(In_{0.5}Ga_{0.5})Se₂ | 0.35 | 20 | Sputtering | 300 |
| | | | | method | |
| | | | | In + Ga + Se | |
| Comparative | None | | | | |
| Example 12 | | | | | |
| Example 44 | Cu(In_{0.5}Ga_{0.5})Se₂ | 0.35 | 20 | Sputtering | 300 |
| | | | | method | |
| | | | | In + Ga + Se | |

### Examples 45 to 49

As the first p-type absorber layer, the material shown in Table 17 was used. At the p-type absorber layer film forming step, the flux was set such that the Ib group/IIIb group composition ratio immediately after formation of the film might be a value shown in Table 17.

After formation of the first p-type absorber layer, the substrate was immersed in a potassium cyanide aqueous solution (10 wt %) for 5 minutes, and removal of the secondary phase Ib group-VIb group compound contained in the first p-type absorber layer was performed.

After the secondary phase removing treatment of the first p-type absorber layer, a second absorber layer was formed on the first p-type absorber layer by the vacuum evaporation method.

The substrate was placed within the chamber of the PVD machine, and the inside of the chamber was evacuated. The ultimate pressure within the vacuum chamber was 1.0×10⁻⁸ torr.

Then, after the substrate was heated to 200° C. and the temperature was stabilized, the shutters of the respective K cells of In, Ga and Se were opened to deposit In, Ga and Se on the substrate. At a point of time when a layer with a thickness of approximately 20 nm was formed on the substrate by this deposition, the shutters of the K cells of In and Ga were closed. With respect to Se, supply thereof was subsequently continued.

Then, the substrate was heated within the chamber to the temperature of the heat treatment shown in Table 18 to perform the heat treatment. The heat treatment time was 2 min. Then, after the substrate was cooled to 200° C., the shutter of the K cell of Se was closed to complete the formation of the second absorber layer.

Except the description above, solar cells of Examples 45 to 49 were produced by the same method as that in Example 26.

The compound used for the first p-type absorber layer, the Ib group/IIIb group composition ratio in the first p-type absorber layer immediately after formation of the film, the Ib group/IIIb group composition ratio after the secondary phase removing treatment, the half width value of the luminescence with the narrowest half width in the photoluminescence spectrum and the cathodoluminescence spectrum of the first p-type absorber layer, the value of k in the measurement of the excitation light intensity dependence of the intensity of photoluminescence, and the secondary phase removing method are shown in Table 17.

The compound used for the second absorber layer, the ratio of the Ib group/IIIb group composition contained in the second absorber layer obtained in the AES measurement, the film thickness of the second absorber layer, the method for producing the second absorber layer, and the film forming temperature are shown in Table 18.

### Examples 50 to 54

As the first p-type absorber layer, the material shown in Table 17 was used. At the first p-type absorber layer film forming step, the flux was set such that the Ib group/IIIb group composition ratio immediately after formation of the film might be a value shown in Table 17.

After formation of the first p-type absorber layer, the substrate was immersed in a potassium cyanide aqueous solution (10 wt %) for 5 minutes to perform removal of the secondary phase Ib group-VIb group compound contained in the first p-type absorber layer.

Then, the substrate on which the first p-type absorber layer was formed was placed in the sputtering apparatus to perform formation of a second absorber layer by the sputtering method.

Hereinafter, details of formation of the second absorber layer by the sputtering method will be described.

The substrate was placed within the sputtering apparatus, and the inside of the apparatus was evacuated. The ultimate pressure was 1.0×10⁻⁶ torr. After evacuation, the temperature of the substrate was kept at room temperature (30° C.). Then, while gaseous Ar was continuously supplied into the chamber, a target composed of (In_{0.5}Ga_{0.5})₂Se₃ was sputtered within the chamber to form a film on the substrate placed facing the target.

After formation of the film was completed, the substrate was moved into a heat treatment furnace to perform a heat treatment. At the heat treatment step, the substrate was heated in an H₂Se atmosphere at a temperature shown in Table 18 for 2 min, thereby to form a second absorber layer with a thickness of 20 nm. After the heat treatment, the substrate was cooled to 50° C., and taken out, and the second absorber layer forming step was completed.

Except the description above, solar cells of Examples 50 to 54 were produced by the same method as that in Example 26.

The compound used for the first p-type absorber layer, the Ib group/IIIb group composition ratio in the first p-type absorber layer immediately after formation of the film, the Ib group/IIIb group composition ratio after the secondary phase removing treatment, the half width value of the luminescence with the narrowest half width in the photoluminescence spectrum and the cathodoluminescence spectrum of the first p-type absorber layer, the value of k in the measurement of the excitation light intensity dependence of the intensity of photoluminescence, and the secondary phase removing method are shown in Table 17.

The compound used for the second absorber layer, the ratio of the Ib group/IIIb group composition contained in the second absorber layer obtained in the AES measurement, the film thickness of the second absorber layer, the method for producing the second absorber layer, and the film forming temperature are shown in Table 18.

TABLE 17

| | First p-type absorber layer | | | | | | | |
|---|---|---|---|---|---|---|---|---|
| | | | Ib group/ | | | | | |
| | | | IIIb group | | | | | |
| | | | composition | | | | | |
| | | Ib group/ | ratio of | | | | | |
| | | IIIb group | first p-type | | | | | |
| | | composition | absorber | | | | | |
| | | ratio | layer (after | | | | | |
| | | immediately | secondary | | | | | Secondary |
| | | after | phase | Photo- | Cathodo- | Photo- | | phase |
| | | formation | removing | luminescence | lumincscence | luminescence | Production | removing |
| Table 17 | Material | of film | treatment) | half width (meV) | half width (meV) | k value | method | treatment |
| Example 45 | Cu(In_{0.5}Ga_{0.5})Se₂ | 1.31 | 1.00 | 6 | 6 | 1.19 | Vacuum | KCN |
| | | | | | | | evaporation | etching |
| | | | | | | | method | |
| Example 46 | Cu(In_{0.5}Ga_{0.5})Se₂ | 1.31 | 1.00 | 6 | 6 | 1.19 | Vacuum | KCN |
| | | | | | | | evaporation | etching |
| | | | | | | | method | |
| Example 47 | Cu(In_{0.5}Ga_{0.5})Se₂ | 1.31 | 1.00 | 6 | 6 | 1.19 | Vacuum | KCN |
| | | | | | | | evaporation | etching |
| | | | | | | | method | |
| Example 48 | Cu(In_{0.5}Ga_{0.5})Se₂ | 1.31 | 1.00 | 6 | 6 | 1.19 | Vacuum | KCN |
| | | | | | | | evaporation | etching |
| | | | | | | | method | |
| Example 49 | Cu(In_{0.5}Ga_{0.5})Se₂ | 1.31 | 1.00 | 6 | 6 | 1.19 | Vacuum | KCN |
| | | | | | | | evaporation | etching |
| | | | | | | | method | |
| Example 50 | Cu(In_{0.5}Ga_{0.5})Se₂ | 1.31 | 1.00 | 6 | 6 | 1.19 | Vacuum | KCN |
| | | | | | | | evaporation | etching |
| | | | | | | | method | |
| Example 51 | Cu(In_{0.5}Ga_{0.5})Se₂ | 1.31 | 1.00 | 6 | 6 | 1.19 | Vacuum | KCN |
| | | | | | | | evaporation | etching |
| | | | | | | | method | |
| Example 52 | Cu(In_{0.5}Ga_{0.5})Se₂ | 1.31 | 1.00 | 6 | 6 | 1.19 | Vacuum | KCN |
| | | | | | | | evaporation | etching |
| | | | | | | | method | |
| Example 53 | Cu(In_{0.5}Ga_{0.5})Se₂ | 1.31 | 1.00 | 6 | 6 | 1.19 | Vacuum | KCN |
| | | | | | | | evaporation | etching |
| | | | | | | | method | |
| Example 54 | Cu(In_{0.5}Ga_{0.5})Se₂ | 1.31 | 1.00 | 6 | 6 | 1.19 | Vacuum | KCN |
| | | | | | | | evaporation | etching |
| | | | | | | | method | |

TABLE 18

| | Second absorber layer | | | | | |
|---|---|---|---|---|---|---|
| | | Ib group/ | | | Film | Temperature |
| | | IIIb group | Film | | forming | of heat |
| | | composition | thickness | Production | temperature | treatment |
| Table 18 | Material | ratio | (nm) | method | (° C.) | (° C.) |
| Example 45 | Cu(In_{0.5}Ga_{0.5})Se₂ | 0.10 | 20 | Vacuum evaporation method | 200 | 250 |
| | | | | In + Ga + Se + heat treatment | | |
| Example 46 | Cu(In_{0.5}Ga_{0.5})Se₂ | 0.35 | 20 | Vacuum evaporation method | 200 | 300 |
| | | | | In + Ga + Se + heat treatment | | |
| Example 47 | Cu(In_{0.5}Ga_{0.5})Se₂ | 0.45 | 20 | Vacuum evaporation method | 200 | 350 |
| | | | | In + Ga + Se + heat treatment | | |
| Example 48 | Cu(In_{0.5}Ga_{0.5})Se₂ | 0.60 | 20 | Vacuum evaporation method | 200 | 400 |
| | | | | In + Ga + Se + heat treatment | | |
| Example 49 | Cu(In_{0.5}Ga_{0.5})Se₂ | 0.80 | 20 | Vacuum evaporation method | 200 | 450 |
| | | | | In + Ga + Se + heat treatment | | |
| Example 50 | Cu(In_{0.5}Ga_{0.5})Se₂ | 0.10 | 20 | Sputtering method | 30 | 250 |
| | | | | In + Ga + Se + heat treatment | | |
| Example 51 | Cu(In_{0.5}Ga_{0.5})Se₂ | 0.35 | 20 | Sputtering method | 30 | 300 |
| | | | | In + Ga + Se + heat treatment | | |
| Example 52 | Cu(In_{0.5}Ga_{0.5})Se₂ | 0.45 | 20 | Sputtering method | 30 | 350 |
| | | | | In + Ga + Se + heat treatment | | |
| Example 53 | Cu(In_{0.5}Ga_{0.5})Se₂ | 0.60 | 20 | Sputtering method | 30 | 400 |
| | | | | In + Ga + Se + heat treatment | | |
| Example 54 | Cu(In_{0.5}Ga_{0.5})Se₂ | 0.80 | 20 | Sputtering method | 30 | 450 |
| | | | | In + Ga + Se + heat treatment | | |

(Evaluation of Thin Film Type Solar Cell)

The properties of the respective solar cells of Examples 1 to 54 and Comparative Examples 1 to 12 are shown in Table 19 and Table 20.

It was recognized that the conversion efficiency of the solar cells of Examples 1 to 54 having the first absorber layer and the second absorber layer in which the first absorber layer is the p-type semiconductor layer containing the Ib group element, the IIIb group element, and the VIb group element, and including a peak of luminescence whose half width is not less than 1 meV and not more than 15 meV in the photoluminescence spectrum or the cathodoluminescence spectrum, and the second absorber layer contains the Ib group element, the IIIb group element, and the VIb group element, the composition ratio of the Ib group element to the IIIb group element is not less than 0.1 and less than 1.0, and the second absorber layer is provided on the side of the light entering surface of the first absorber layer is larger than that of the solar cells of Comparative Examples 1 to 12 not including the first p-type absorber layer or the second absorber layer.

It was recognized that the open-circuit voltage and conversion efficiency of the solar cells of Examples 1 to 6 having the first absorber layer and the second absorber layer in which the first absorber layer is the p-type semiconductor layer containing the Ib group element, the IIIb group element, and the VIb group element, and including a peak of luminescence whose half width is not less than 1 meV and not more than 15 meV in the photoluminescence spectrum or the cathodoluminescence spectrum, and the second absorber layer contains the Ib group element, the IIIb group element, and the VIb group element, the composition ratio of the Ib group element to the IIIb group element is not less than 0.1 and less than 1.0, and the second absorber layer is provided on the side of the light entering surface of the first absorber layer are larger than those of the solar cell of Comparative Example 1 including the first p-type semiconductor layer containing the Ib group element, the IIIb group element, and the VIb group element and including a peak of luminescence whose half width is not less than 1 meV and not more than 15 meV in the photoluminescence spectrum or the cathodoluminescence spectrum but including no second absorber layer and the solar cell of Comparative Example 2 including the second absorber layer containing the Ib group element, the IIIb group element, and the VIb group element with the composition ratio of the Ib group element to the IIIb group element being not less than 0.1 and less than 1.0 and provided on the first p-type absorber layer, the half width being out of the range of not less than 1 meV and not more than 15 meV, i.e., 40 meV in the photoluminescence spectrum or the cathodoluminescence spectrum of the first p-type absorber layer.

It was recognized that the open-circuit voltage and conversion efficiency of the solar cells of Examples 2 to 5 and Examples 7 to 54 having the first absorber layer and the second absorber layer in which the first absorber layer is the p-type semiconductor layer containing the Ib group element, the IIIb group element, and the VIb group element with the ratio of Ib group element/IIIb group element being 1.00, and including a peak of luminescence whose half width is not less than 1 meV and not more than 15 meV in a photoluminescence spectrum or a cathodoluminescence spectrum are larger than those of the solar cells of Examples 1 and 6 in which the first absorber layer is the p-type semiconductor layer containing the Ib group element, the IIIb group element, and the VIb group element, and including a peak of luminescence whose half width is not less than 1 meV and not more than 15 meV in the photoluminescence spectrum or cathodoluminescence spectrum with the ratio of Ib group element/IIIb group element being not 1.00.

It was recognized that the open-circuit voltage and conversion efficiency of the solar cells of Examples 7 to 14 having the first absorber layer and the second absorber layer, including: the first absorber layer that is the p-type semiconductor layer containing the Ib group element, the IIIb group element, and the VIb group element with the ratio of Ib group element/IIIb group element being 1.00, and including a peak of luminescence whose half width is not less than 1 meV and not more than 15 meV in the photoluminescence spectrum or cathodoluminescence spectrum; and the second absorber layer containing the Ib group element, the IIIb group element, and the VIb group element with the composition ratio of the Ib group element to the IIIb group element being not less than 0.1 and less than 1.0 and provided on the first p-type absorber layer are larger than those of the solar cells of Comparative Examples 3 and 4 in which the composition ratio of the Ib group element to the IIIb group element that the second absorber layer contains is out of the range.

It was recognized that the open-circuit voltage and conversion efficiency of the solar cells of Examples 15 to 21 including: the first p-type absorber layer that is the p-type semiconductor layer containing a variety of Ib group elements, IIIb group elements, and VIb group elements with the ratio of Ib group element/IIIb group element being 1.00, and including a peak of luminescence whose half width is not less than 1 meV and not more than 15 meV in the photoluminescence spectrum or the cathodoluminescence spectrum; and the second absorber layer containing the Ib group element, the IIIb group element, and the VIb group element with the composition ratio of the Ib group element to the IIIb group element being not less than 0.1 and less than 1.0 and provided on the first p-type absorber layer are larger than those of the solar cells of Comparative Examples 5 to 11 each including the first p-type absorber layer with the same composition and the same half width of the luminescence in the photoluminescence or the cathodoluminescence spectrum but having no second absorber layer.

It was recognized that the open-circuit voltage and conversion efficiency of the solar cells of Examples 22 and 25 using the p-type semiconductor layer that is the first p-type absorber layer containing a variety of Ib group elements, IIIb group elements, and VIb group elements with the ratio of Ib group element/IIIb group element being 1.00, and including a peak of luminescence whose half width is not less than 1 meV and not more than 15 meV in the photoluminescence spectrum or the cathodoluminescence spectrum half; and the second absorber layer using the same Ib group element and IIIb group element as those in the first p-type absorber layer are larger than those of the solar cells of Examples 23 and 24 each including the first p-type absorber layer having the same composition and half width of the luminescence in the photoluminescence or the cathodoluminescence spectrum, and using a different Ib group element or IIIb group element from that of the first p-type absorber layer for the second absorber layer.

It was recognized that the open-circuit voltage and conversion efficiency of the solar cell of Example 26 including: the first p-type absorber layer that is the p-type semiconductor layer in which the ratio of Ib group element/IIIb group element is 1.00, and a peak of luminescence whose half width is not less than 1 meV and not more than 15 meV in the photoluminescence spectrum or the cathodoluminescence spectrum is included; and the second absorber layer in which the same Ib group element and IIIb group element as those of the first p-type absorber layer are used for the second absorber layer, and the composition ratio of a plurality of IIIb group elements is the same as that of the first p-type absorber layer are larger than those of the solar cell of Example 27 in which the composition ratio of a plurality of IIIb group elements contained in the second absorber layer is different from that of the first p-type absorber layer.

It was recognized that the conversion efficiency of the solar cell of Example 28 including: the first p-type absorber layer that is the p-type semiconductor layer containing Cu, the IIIb group element, and the VIb group element with the composition ratio of Cu to the IIIb group element being 1.00, and including a peak of luminescence whose half width is not less than 1 meV and not more than 15 meV in the photoluminescence spectrum or the cathodoluminescence spectrum; and the second absorber layer containing Cu, the IIIb group element, and the VIb group element with the composition ratio of Cu to the IIIb group element being not less than 0.1 and less than 1.0 and provided on the first p-type absorber layer is larger than that of that of the solar cell of Example 29 in which the Ib element contained in the first p-type absorber layer and the second absorber layer is not Cu.

It was recognized that the open-circuit voltage and conversion efficiency of the solar cells of Examples 31 to 35 including: the first p-type absorber layer that is the p-type semiconductor layer containing the Ib group element, the IIIb group element, and the VIb group element with the composition ratio of the Ib group element to the IIIb group element being 1.00, and including a peak of luminescence whose half width is not less than 1 meV and not more than 15 meV in the photoluminescence spectrum or the cathodoluminescence spectrum; and the second absorber layer containing the Ib group element, the IIIb group element, and the VIb group element with the composition ratio of the Ib group element to the IIIb group element being not less than 0.1 and less than 1.0 and provided on the first p-type absorber layer in which the film thickness of the second absorber layer is not less than 1 nm and not more than 100 nm are larger than those of the solar cells of Examples 30 and 36 in which the film thickness is out of the range.

It was recognized that the open-circuit voltage and conversion efficiency of the solar cells of Examples 1 to 6 in which the value of k was within the range of 1<k<2 in the measurement of the photoluminescence when the excitation light dependence or excited electron beam intensity dependence is measured, wherein the relationship between intensity of excitation light or excited electron beam intensity Iₑₓ^{k} and intensity of photoluminescence I_{PL} is represented by the following expression (2):

[Expression 5]

I_{PL}∝Iₑₓ^{k} (Expression 2)

are larger than those of the solar cell of Comparative Example 2 in which the value of k is out of the range.

It was recognized that the open-circuit voltage and conversion efficiency of the solar cells of Examples 38 to 41 comprising the step of forming the film such that the ratio of the Ib group element to the IIIb group element may be more than 1.0, and subsequently removing the secondary phase Ib group-VIb group compound at the first p-type absorber layer forming step are larger than those of the solar cell of Example 37 comprising no secondary phase removing step.

TABLE 19

| | | Short- | | |
|---|---|---|---|---|
| | | circuit | | |
| | | current | | |
| | Open-circuit | density | | Conversion |
| | voltage Voc | Jsc | | efficiency |
| | (V) | (mA/cm2) | F.F. | (%) |
| Comparative Example 1 | 0.389 | 37.4 | 0.562 | 8.2 |
| Comparative Example 2 | 0.391 | 38.1 | 0.600 | 8.9 |
| Example 1 | 0.405 | 34.0 | 0.670 | 9.2 |
| Example 2 | 0.481 | 35.2 | 0.680 | 11.5 |
| Example 3 | 0.482 | 36.1 | 0.695 | 12.1 |
| Example 4 | 0.492 | 35.1 | 0.683 | 11.8 |
| Example 5 | 0.499 | 35.2 | 0.689 | 12.1 |
| Example 6 | 0.442 | 34.0 | 0.621 | 9.3 |
| Comparative Example 3 | 0.450 | 27.2 | 0.605 | 7.4 |
| Example 7 | 0.456 | 32.5 | 0.644 | 9.5 |
| Example 8 | 0.490 | 36.2 | 0.690 | 12.2 |
| Example 9 | 0.480 | 37.5 | 0.688 | 12.4 |
| Example 10 | 0.470 | 38.6 | 0.677 | 12.3 |
| Example 11 | 0.462 | 39.8 | 0.678 | 12.5 |
| Example 12 | 0.492 | 38.9 | 0.677 | 13.0 |
| Example 13 | 0.495 | 38.8 | 0.681 | 13.1 |
| Example 14 | 0.491 | 39.9 | 0.690 | 13.5 |
| Comparative Example 4 | 0.389 | 37.5 | 0.550 | 8.0 |
| Comparative Example 5 | 0.601 | 18.2 | 0.490 | 5.4 |
| Comparative Example 6 | 0.551 | 27.5 | 0.520 | 7.9 |
| Comparative Example 7 | 0.572 | 25.2 | 0.510 | 7.4 |
| Comparative Example 8 | 0.490 | 24.2 | 0.501 | 5.9 |
| Comparative Example 9 | 0.550 | 17.2 | 0.540 | 5.1 |
| Comparative Example 10 | 0.620 | 20.3 | 0.592 | 7.5 |
| Comparative Example 11 | 0.650 | 15.2 | 0.550 | 5.4 |
| Example 15 | 0.790 | 23.1 | 0.670 | 12.2 |
| Example 16 | 0.650 | 31.0 | 0.750 | 15.1 |
| Example 17 | 0.680 | 30.2 | 0.740 | 15.2 |
| Example 18 | 0.590 | 30.1 | 0.660 | 11.7 |
| Example 19 | 0.710 | 21.8 | 0.710 | 11.0 |
| Example 20 | 0.750 | 22.0 | 0.730 | 12.0 |
| Example 21 | 0.820 | 18.3 | 0.680 | 10.2 |
| Example 22 | 0.492 | 36.3 | 0.692 | 12.4 |
| Example 23 | 0.488 | 33.1 | 0.675 | 10.9 |
| Example 24 | 0.812 | 17.5 | 0.675 | 9.6 |
| Example 25 | 0.815 | 18.3 | 0.679 | 10.1 |
| Example 26 | 0.710 | 30.5 | 0.766 | 16.6 |
| Example 27 | 0.690 | 31.2 | 0.750 | 16.1 |

TABLE 20

| | | Short-circuit | | |
|---|---|---|---|---|
| | | current density | | |
| | Open circuit | Jsc | | Conversion |
| | voltage Voc (V) | (mA/cm2) | F.F. | efficiency (%) |
| Example 28 | 0.691 | 31.3 | 0.770 | 16.7 |
| Example 29 | 0.950 | 16.0 | 0.670 | 10.2 |
| Example 30 | 0.620 | 33.5 | 0.740 | 15.4 |
| Example 31 | 0.691 | 33.0 | 0.760 | 17.3 |
| Example 32 | 0.710 | 32.0 | 0.780 | 17.7 |
| Example 33 | 0.700 | 31.6 | 0.770 | 17.0 |
| Example 34 | 0.698 | 31.0 | 0.765 | 16.6 |
| Example 35 | 0.695 | 30.4 | 0.755 | 16.0 |
| Example 36 | 0.688 | 30.0 | 0.740 | 15.3 |
| Example 37 | 0.589 | 32.2 | 0.688 | 13.0 |
| Example 38 | 0.678 | 32.6 | 0.744 | 16.4 |
| Example 39 | 0.668 | 32.3 | 0.745 | 16.1 |
| Example 40 | 0.688 | 33.0 | 0.750 | 17.0 |
| Example 41 | 0.690 | 33.5 | 0.751 | 17.4 |
| Example 42 | 0.708 | 33.3 | 0.755 | 17.8 |
| Example 43 | 0.680 | 32.1 | 0.744 | 16.2 |
| Comparative | 0.520 | 33.0 | 0.510 | 8.8 |
| Example 12 | | | | |
| Example 44 | 0.650 | 32.2 | 0.720 | 15.1 |
| Example 45 | 0.688 | 30.2 | 0.702 | 14.6 |
| Example 46 | 0.711 | 33.6 | 0.761 | 18.2 |
| Example 47 | 0.709 | 33.6 | 0.760 | 18.1 |
| Example 48 | 0.708 | 33.4 | 0.755 | 17.9 |
| Example 49 | 0.705 | 33.5 | 0.755 | 17.8 |
| Example 50 | 0.610 | 29.5 | 0.680 | 12.2 |
| Example 51 | 0.660 | 32.3 | 0.740 | 15.8 |
| Example 52 | 0.655 | 32.1 | 0.731 | 15.4 |
| Example 53 | 0.649 | 31.2 | 0.720 | 14.6 |
| Example 54 | 0.640 | 31.0 | 0.716 | 14.2 |

### INDUSTRIAL APPLICABILITY

According to the present invention, the solar cell, and the process for producing a solar cell can be provided in which the open-circuit voltage can be increased, and as a result, the conversion efficiency can be increased compared to the conventional solar cell including the chalcopyrite p-type semiconductor film including a peak of luminescence whose half width is not less than 1 meV and not more than 15 meV in a photoluminescence spectrum or a cathodoluminescence spectrum as the absorber layer.

### REFERENCE SIGNS LIST

2 . . . conventional solar cell, 4 . . . solar cell according to one embodiment of the present invention, 6 . . . soda-lime glass, 8 . . . back electrode layer, 10 . . . first p-type absorber layer, 12 . . . second absorber layer, 14 . . . n-type semiconductor layer, 16 . . . semi-insulating layer, 18 . . . window layer (transparent conductive layer), 20 . . . upper electrode (extraction electrode).

1. A solar cell comprising:
a first absorber layer and a second absorber layer,
the first absorber layer being a p-type semiconductor layer containing a Ib group element, a IIIb group element, and a VIb group element, and including a peak of luminescence whose half width is not less than 1 meV and not more than 15 meV in a photoluminescence spectrum or a cathodoluminescence spectrum,
the second absorber layer containing a Ib group element, a IIIb group element, and a VIb group element, a composition ratio of the Ib group element to the IIIb group element being not less than 0.1 and less than 1.0, the second absorber layer being provided on a side of a light entering surface of the first absorber layer.

2. The solar cell according to claim 1, wherein the composition ratio of the Ib group element to the IIIb group element contained in the first absorber layer is 1.0.

3. The solar cell according to claim 1, wherein the Ib group element and IIIb group element contained in the second absorber layer formed on the first absorber layer are the same as the Ib group element and IIIb group element contained in the first absorber layer.

4. The solar cell according to claim 1, wherein the Ib group element contained in the first absorber layer and the second absorber layer is Cu.

5. The solar cell according to claim 1, wherein a thickness of the second absorber layer formed on the first absorber layer is in the range of not less than 1 nm and not more than 100 nm.

6. The solar cell according to claim 1, wherein a layer formed by forming such that the ratio of the Ib group element to the IIIb group element may be more than 1.0, and subsequently removing a secondary phase Ib group-VIb group compound is used as the first absorber layer.

7. A process for producing a solar cell according to claim 1, comprising forming the second absorber layer by one method selected from a vacuum evaporation method and a sputtering method.

8. The process for producing a solar cell according to claim 1, wherein in addition to the one method selected from a vacuum evaporation method and a sputtering method, the second absorber layer is formed by performing a heat treatment at a subsequent step.
